(19) United States
(12) Patent Application Publication
(10) Pub. No.: US 2024/0113172 A1
(43) Pub. Date: Apr. 4, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yi-Tse Hung, Hsinchu (TW); Meng-Zhan Li; Tzu-Chiang Chen, Changhua County (TW); Chao-Ching Cheng, Hsinchu City (TW); Iuliana Radu, Hsinchu City (TW)

(73) Assignee: Taiwan Semiconductor Manufacturing Company, Ltd., Hsinchu (TW)

(21) Appl. No.: 18/178,522

(22) Filed: Mar. 5, 2023

Related U.S. Application Data
(60) Provisional application No. 63/411,642, filed on Sep. 30, 2022.

(51) Int. Cl. H01L 29/08; H01L 21/8234; H01L 29/10; H01L 29/18; H01L 29/66; H01L 29/78

(52) U.S. Cl. CPC H01L 29/0847; H01L 21/823412; H01L 21/823418; H01L 29/1033; H01L 29/18; H01L 29/66795; H01L 29/7851

(57) ABSTRACT

A semiconductor device includes a substrate, a channel layer, a gate structure, source/drain regions, and an insulating layer. The channel layer is disposed over the substrate. The gate structure is disposed over the channel layer. The source/drain regions are disposed over the substrate and disposed at two opposite sides of the channel layer. The insulating layer is disposed between the channel layer and the source/drain regions.

### CROSS-REFERENCE TO RELATED APPLICATION

This application claims the priority benefit of U.S. provisional application Ser. No. 63/411,642, filed on Sep. 30, 2022. The entirety of the above-mentioned patent application is hereby incorporated by reference herein and made a part of this specification.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 are schematic views of various stages in a manufacturing method of a semiconductor device in accordance with some embodiments of the disclosure.

FIG. 10 and FIG. 11 are schematic views showing a semiconductor device in accordance with alternative embodiments of the disclosure.

FIG. 12 and FIG. 13 are schematic views showing a semiconductor device in accordance with alternative embodiments of the disclosure.

FIG. 14 is a schematic cross-sectional view showing a semiconductor device in accordance with some embodiments of the disclosure.

FIG. 15 and FIG. 16 are schematic cross-sectional views respectively showing a semiconductor device in accordance with alternative embodiments of the disclosure.

FIG. 17 is a flow chart illustrating a method for manufacturing a semiconductor device in accordance with some embodiments of the disclosure.

FIG. 18 is a schematic cross-sectional view showing a semiconductor device in accordance with some embodiments of the disclosure.

FIG. 19 and FIG. 20 are schematic cross-sectional views respectively showing a semiconductor device in accordance with alternative embodiments of the disclosure.

FIG. 21 is a flow chart illustrating a method for manufacturing a semiconductor device in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a structure containing one or more semiconductor devices, and is not intended to limit the scope of the disclosure. Accordingly, it is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto. Embodiments of the disclosure describe the exemplary manufacturing process of the structure(s) formed with one or more semiconductor devices such as transistors and the integration structures fabricated there-from. Certain embodiments of the disclosure are related to the structures including semiconductor transistors and other elements. The substrates and/or wafers may include one or more types of integrated circuits or electronic components therein. The semiconductor device(s) may be formed on a bulk semiconductor substrate or a silicon/germanium-on-insulator substrate.

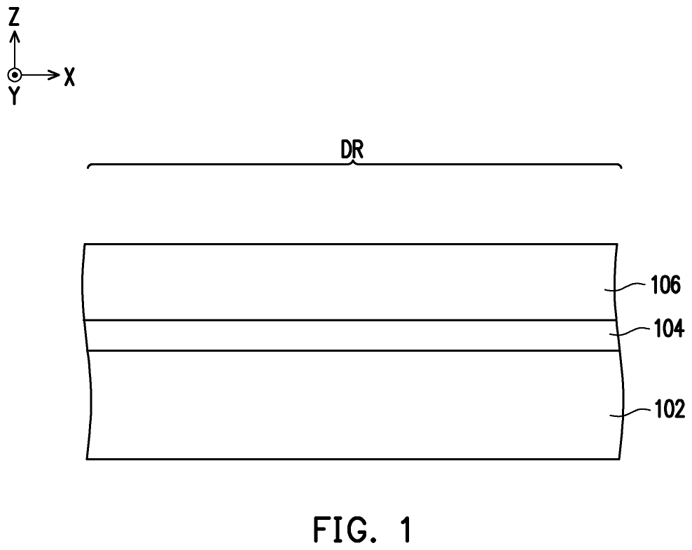

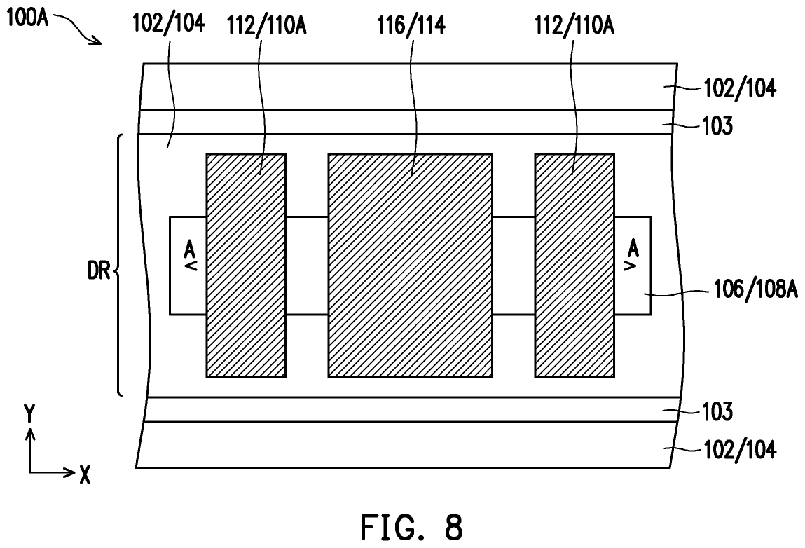

FIG. 1 through FIG. 9 are schematic views of various stages in a manufacturing method of a semiconductor device in accordance with some embodiments of the disclosure. From FIG. 1 through FIG. 7 and FIG. 9, schematic cross-section views of a device region DR of the structure along a line A-A depicted in FIG. 8 are shown, while in FIG. 8, a schematic top view of the structure is shown.

Referring to FIG. 1, in some embodiments, a substrate 102 having an overlay layer 104 and a semiconductor fin 106 stacked thereon is provided. As shown in FIG. 1, in some embodiments, the overlay layer 104 and the semiconductor fin 106 are formed on the substrate 102 within the device region DR. It is understood that isolation structures 103 (seen in FIG. 8) may be included in the substrate 102 and the device region DR may be defined through the arrangement of the isolation structures 103. From FIG. 1 to FIG. 7, only a portion of the device region DR of the substrate 102 is shown for illustration purposes. Referring to FIG. 1, in some embodiments, the substrate 102 includes a semiconductor substrate. In one embodiment, the substrate 102 comprises a bulk semiconductor substrate such as a crystalline silicon substrate, or a doped semiconductor substrate (e.g., p-type or n-type semiconductor substrate). In one embodiment, the substrate 102 comprises a silicon-on-insulator (SOI) substrate or a germanium-on-insulator (GeOI) substrate. In certain embodiments, the substrate 102 includes one or more doped regions or various types of doped regions, depending on design requirements. In some embodiments, the doped regions are doped with p-type and/or n-type dopants. For example, the p-type dopants are boron or BF₂ and the n-type dopants are phosphorus or arsenic. In some embodiments, the substrate 102 includes a semiconductor substrate made of other suitable elemental semiconductor, such as diamond or germanium; a suitable compound semiconductor, such as gallium arsenide, silicon carbide (SiC), indium arsenide, or indium phosphide; or a suitable alloy semiconductor, such as silicon germanium carbide, gallium arsenic phosphide, or gallium indium phosphide. In some embodiments, the substrate 102 includes a sapphire substrate. In some embodiments, the substrate 102 includes a glass substrate such as indium tin oxide (ITO) substrate.

In some embodiments, the isolation structures 103 in FIG. 8 are trench isolation structures, such as shallow isolation trench (STI) structures or deep isolation trench (DTI) structures. The DTI structures may include full DTI (FDTI) structures or partial DTI (PDTI) structures. In other embodiments, the isolation structures 103 includes local oxidation of silicon (LOCOS) structures. In some embodiments, the insulator material of the isolation structures 103 includes silicon oxide, silicon nitride, silicon oxynitride, a spin-on dielectric material, or a low-k dielectric material. In one embodiment, the insulator material may be formed by chemical vapor deposition (CVD) such as high-density-plasma chemical vapor deposition (HDP-CVD) and sub-atmospheric CVD (SACVD) or formed by spin-on.

In some embodiments, the overlay layer 104 includes a dielectric layer. A material of the overlay layer 104 may include a dielectric material, such as silicon oxide, silicon nitride, silicon carbide, silicon oxynitride, silicon carbonitride, silicon carbide oxynitride, a high-k dielectric material, or a combination thereof. It should be noted that the high-k dielectric materials are generally dielectric materials having a dielectric constant greater than 3.9 or even greater than about 10. High-k dielectric materials include metal oxides. Examples of metal oxides used for high-k dielectric materials include oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. For example, the overlay layer 104 includes a silicon nitride layer. In some embodiments, the overlay layer 104 includes a single-layer structure or a multilayer structure having different material layers. In some embodiments, the overlay layer 104 is optional and may be omitted.

In some embodiments, the semiconductor fin 106 is disposed on the overlay layer 104 over the substrate 102. For example, the overlay layer 104 is disposed between the substrate 102 and the semiconductor fin 106 along a direction Z (may also referred to as a stacking direction or a vertical direction). As shown in FIG. 8, the semiconductor fin 106 extends along a direction X over the substrate 102, for example. The direction X may be perpendicular to the direction Z, and may be referred to as a first horizontal direction. The material of the semiconductor fin 106 may include silicon, germanium, silicon-germanium or the like, which can be doped or undoped with p-type dopants or n-type dopants. For example, the p-type dopants are boron or BF₂ and the n-type dopants are phosphorus or arsenic. In some embodiments, the semiconductor fin 106 is a doped poly-silicon or a undoped poly-silicon. The formation of the semiconductor fin 106 may include forming a blanket layer of a suitable material over the substrate 102 to cover up the overlay layer 104, and then patterning the suitable material blanket layer to form the semiconductor fin 106 on the overlay layer 104 over the substrate 102. The suitable material blanket layer for the semiconductor fin 106 may be formed by a suitable deposition process (such as CVD), and the patterning process may include photolithograph and etching processes. The etching process includes a dry etching, a wet etching, or a combination thereof, in some embodiments.

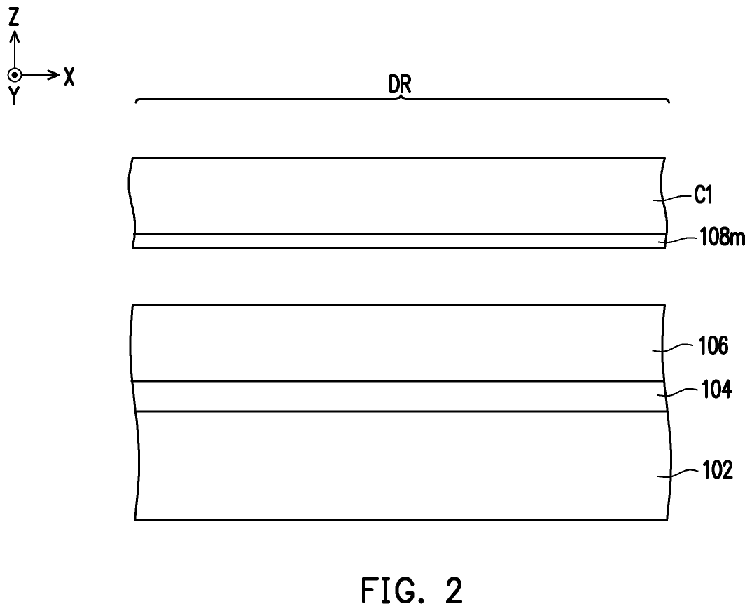

Referring to FIG. 2, in some embodiments, a channel material layer 108m is provided. In some embodiments, the channel material layer 108m is carried by a carrier C1, and the carrier C1 and the channel material layer 108m are moved to the position above the substrate 102. In one embodiment, the channel material layer 108m is to be placed on a predetermined location within the device region DR. In some embodiments, the channel material layer 108m is disposed over the substrate 102 covering the whole device region DR of the substrate 102. In some embodiments, the channel material layer 108m is provided with a pattern and disposed over the substrate 102 covering a portion of the device region DR of the substrate 102, such as covering the portion of the device region where the semiconductor fin 106 disposed at. A material of the channel material layer 108m may include low dimensional materials. For example, the low dimensional materials include nanoparticles, one-dimensional (1D) materials such as carbon nanotubes (CNT), nanoribbon or nanowires and two-dimensional (2D) materials such as graphene, hexagonal boron nitride (h-BN), black phosphorus and transition metal dichalcogenides (TMDs). Among the 2D materials, different types of 2D materials may be classified based on their behaviors as semiconducting 2D materials (e.g. 2H TMDs), metallic 2D materials (e.g. 1T TMDs), and insulating 2D materials (e.g. h-BN). TMDs have the chemical formula MX₂, where M is a transition metal such as molybdenum (Mo) or tungsten (W) and X is a chalcogen such as sulfur (S), selenium (Se) or tellurium (Te). For TMDs having various crystal structures, the most common crystal structure is the 2H-phase with trigonal symmetry, which results in semiconducting characteristics (e.g. MoS₂, WS₂, MoSe₂ or WSe₂). Another possible crystal structure of TMDs is the 1T phase, which results in metallic characteristics (e.g. WTe₂). TMD bulk crystals are formed of monolayers (may also referred to as atomic layers) bound to each other by Van-der-Waals attraction. TMD monolayers have a direct band gap, and can be used in electronic devices such as TMD-based field-effect transistors (TMD-FETs).

The formation of the channel material layer 108m involves the methods of pulse lase deposition (PLD), CVD, atomic layer deposition (ALD) such as plasma-enhanced atomic layer deposition (PEALD), solution based chemical synthesis and/or mechanical or liquid exfoliation. For example, the formation of the channel material layer 108m involves CVD selectively forming monolayer(s) of TMD such as 2H phase of MoS₂, WS₂, MoSe₂ or WSe₂ and then transferred to the carrier C1. In some embodiments, the channel material layer 108m includes carbon nanotubes or nanoribbons.

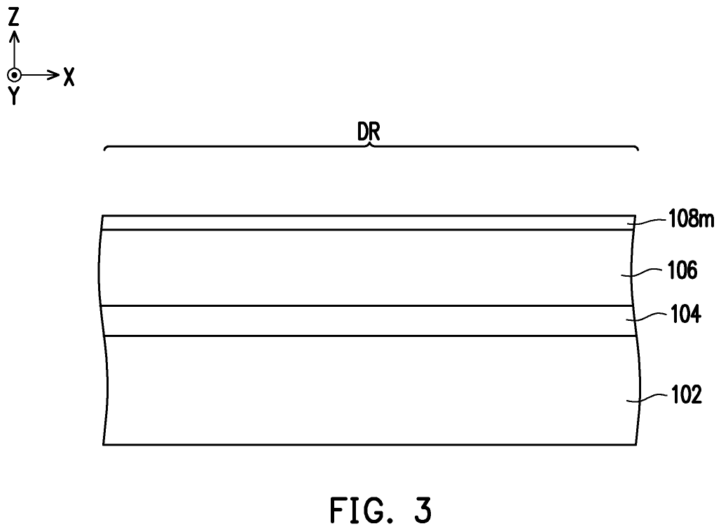

Referring to FIG. 3, in some embodiments, the channel material layer 108m is transferred onto the substrate 102 and is disposed on the semiconductor fin 106. For example, the semiconductor fin 106 is disposed between the overlay layer 104 and the channel material layer 108m. In one embodiment, the channel material layer 108m includes one or a few atomic layers of the low dimensional materials. The channel material layer 108m may include 1, 2, 3, 4, 5, 6, 7, 8, 9, or 10 atomic layers of the low dimensional materials. For example, each atomic layer of the low dimensional materials may have a thickness of about 0.3 nm to about 1 nm.

Alternatively, in some embodiments, the channel material layer 108m may be formed through a growth process over the substrate 102 and directly on the semiconductor fin 106. The growth process utilizing patterned nucleation seeds for forming TMDs is a well-controlled process and the formation may be performed on-site (at the same location). In some embodiments, the growth process includes a CVD process. The CVD process may include a process performed by, for example, electron cyclotron resonance CVD (ECR-CVD), microwave plasma CVD, plasma enhanced CVD (PECVD), low-pressure CVD (LPCVD), thermal CVD or hot filament CVD. In other embodiments, the growth process is a physical vapor deposition (PVD) process. Compared with the transferring formation method, the growth process is well applicable for high density or fine pitch integrated circuitry.

In some embodiments, the channel material layer 108m is disposed over the substrate 102 covering the whole device region DR of the substrate 102. In some embodiments, the channel material layer 108m is provided with a pattern and disposed over the substrate 102 covering a portion of the device region DR of the substrate 102. In one embodiment, the pattern of the channel material layer 108m is substantially the same as the pattern of the semiconductor fin 106, as shown in FIG. 8. That is, the channel material layer 108m extends along the direction X over the substrate 102, for example. In one embodiment, the pattern of the channel material layer 108m is larger in span than that of the pattern of the semiconductor fin 106. In some embodiments, the channel material layer 108m and the semiconductor fin 106 are patterned through photolithographic and etching techniques to have substantially the same the pattern.

In the embodiments of which the overlay layer 104 is skipped, the semiconductor fin 106 is disposed directly on the surface of the substrate 102 with the channel material layer 108m directly stacked on the semiconductor fin 106. The disclosure is not limited thereto.

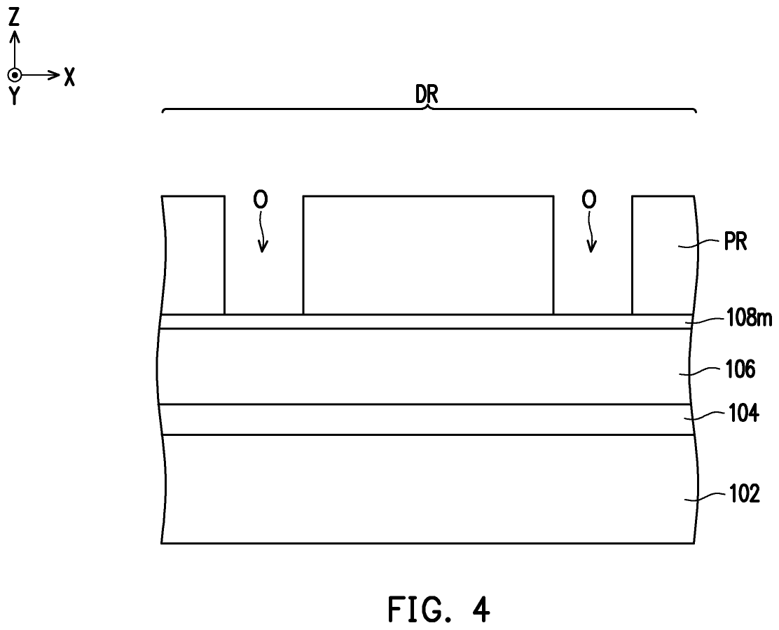

Referring to FIG. 4, in some embodiments, after the channel material layer 108m is provided and disposed on the semiconductor fin 106, a photoresist pattern PR (may referred to a photoresist layer, a photoresist mask layer or pattern, a resist layer, a resist pattern or layer, or a resist mask layer or pattern) having a plurality of openings O is formed on the channel material layer 108m and over the substrate 102. The formation of the photoresist pattern PR includes forming a photoresist material blanket layer (not shown) over the substrate 102 and patterning the photoresist material blanket layer through exposure and development to form the photoresist pattern PR with the openings O. For example, the openings O of the photoresist pattern are formed with the outlines or shapes defining the later-formed source and drain regions and formed at locations corresponding to the later-formed source and drain regions. In some embodiments, the photoresist pattern PR covers the channel material layer 108m with the openings O exposing portions of the channel material layer 108m, as shown in FIG. 4.

In some embodiments, a material of the photoresist material blanket layer for the photoresist pattern PR includes a positive resist material or a negative resist material, that is suitable for a patterning process such as a photolithography process with a mask or a mask-less photolithography process (such as an electron-beam (e-beam) writing or an ion-beam writing). The photoresist material blanket layer may be formed by any suitable method, such as spin-coating or the like.

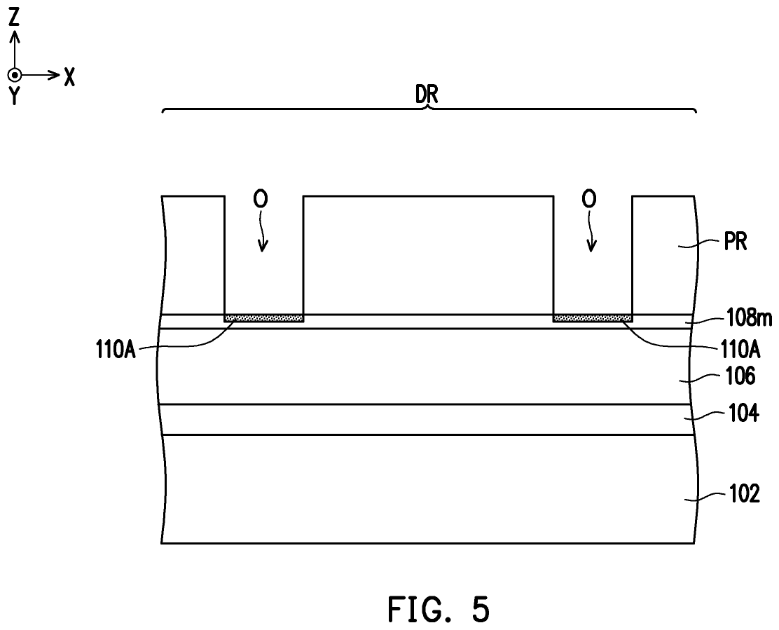

Referring to FIG. 5, in some embodiments, using the photoresist pattern PR as a mask, an oxidation process is performed to convert a portion(s) of the channel material layer 108m into an insulating layer 110A. The oxidation process includes an oxygen plasma process, in one embodiment. In an alternative embodiment, the oxidation process may include an UV-ozone oxidation process. For example, the exposing portions of the channel material layer 108m by the openings O formed in the photoresist pattern PR undergo the oxidation process to be converted into the insulating layer 110A. In some embodiments, the material of the insulating layer 110A includes silicon oxides. In some embodiments, the material of the insulating layer 110A includes an oxide material such as hafnium oxide (e.g. HfO₂), aluminum oxide (e.g. Al₂O₃), or zirconium oxide (e.g. ZrO₂), or other suitable high-k dielectric material(s). It should be noted that the high-k dielectric materials are generally dielectric materials having a dielectric constant larger than 3.9, or greater than about 10, or greater than about 12, or even greater than about 16. For example, the high-k materials may include metal oxide, such as ZrO₂, Gd₂O₃, HfO₂, BaTiO₃, Al₂O₃, LaO₂, TiO₂, Ta₂O₅, Y₂O₃, STO, BTO, BaZrO, HfZrO, HfLaO, HfTaO, HfTiO, or a combination thereof. In some embodiments, the material of the insulating layer 110A includes hexagonal boron nitride (h-BN). However, the disclosure is not limited thereto; alternatively, the material of the insulating layer 110A may include a combination of two or more of the above mentioned materials. In the embodiments of which the channel material layer 108m is MoS₂ or MoSe₂, a material of the insulating layer 110A is MoOx and x is greater than zero. In the embodiments of which the channel material layer 108m is WS₂ or WSe₂, a material of the insulating layer 110A is WOx and x is greater than zero. The insulating layer 110A may have a thickness of about 0.5 nm to about 3 nm, as measured along the direction Z.

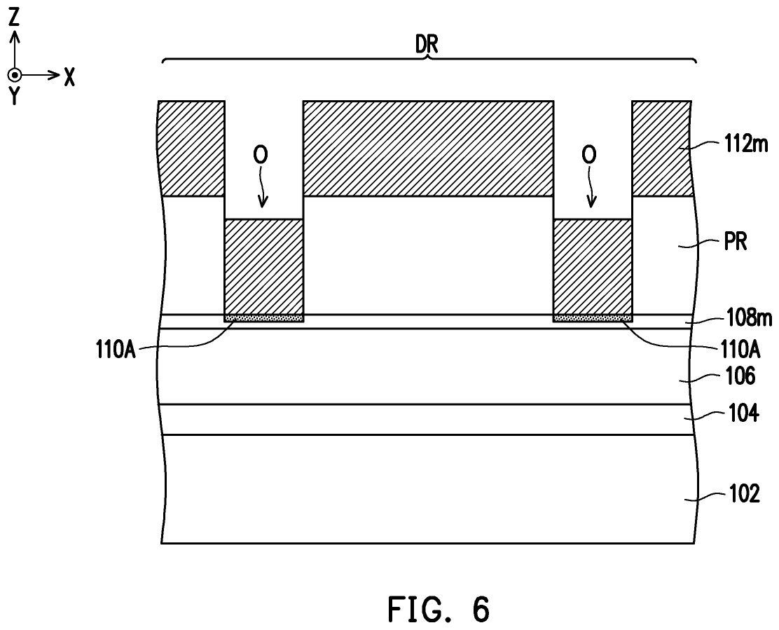

Referring to FIG. 6, in some embodiments, after the formation of the insulating layer 110A, a conductive material layer 112m is formed over the substrate, where the conductive material layer 112m is disposed into the openings O formed in the photoresist pattern PR and further extends onto a surface of the photoresist pattern PR. The formation of the conductive material layer 112m includes conformally forming a metallic material (not shown) over the photoresist pattern PR and the channel material layer 108m by deposition. In some embodiments, the metallic material includes one or more materials selected from titanium (Ti), chromium (Cr), tungsten (W), scandium (Sc), niobium (Nb), nickel (Ni), palladium (Pd), platinum (Pt), silver (Ag), gold (Au), aluminum (Al), ruthenium (Ru), molybdenum (Mo), tantalum (Ta), alloys thereof, and nitrides thereof. For example, the metallic material includes titanium (Ti), chromium (Cr), tungsten (W), scandium (Sc), niobium (Nb), nickel (Ni), palladium (Pd), platinum (Pt), silver (Ag), gold (Au), aluminum (Al) or combinations thereof. In some embodiments, the metallic material is formed by CVD (such as metal organic CVD) or PVD (such as thermal evaporation).

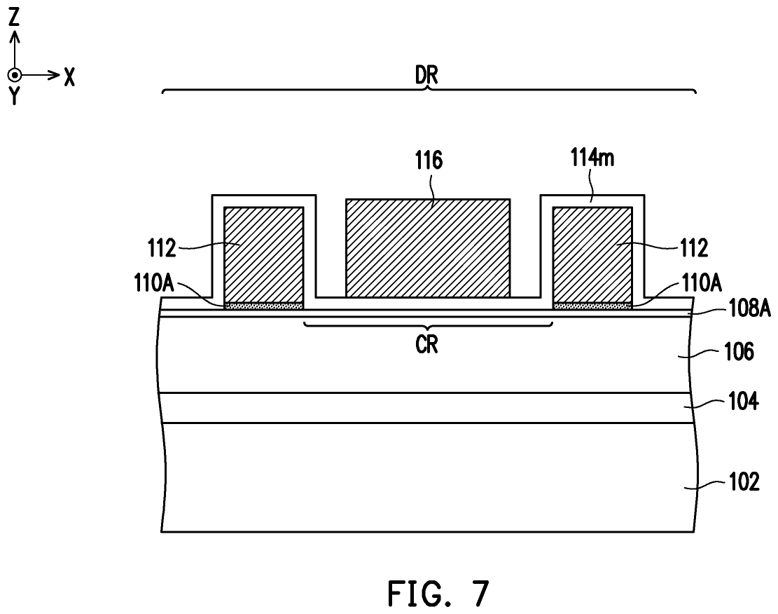

Referring to FIG. 7, in some embodiments, the photoresist pattern PR is removed in a lift-off operation, and the excess conductive material layer 112m disposed on the surface of the photoresist pattern PR (outside the openings O) is then concurrently lift off, thereby the remaining conductive material layer 112m inside the openings O formed in the photoresist pattern PR forms a plurality of source/drain regions 112 (may also referred to as source/drain terminals, source/drain elements, or source/drain structures) separated from each other. For example, the source/drain regions 112 are disposed on (e.g., in physical contact with) the insulating layer 110A over the channel material layer 108m. In some embodiments, the source/drain regions 112 extend along the direction Y over the substrate, as shown in FIG. 8. The direction Y may be perpendicular to the direction Z and the direction X, and may be referred to as a second horizontal direction.

In some embodiments, after the photoresist pattern PR is removed, a portion of the channel material layer 108m disposed laterally next to the insulating layer 110A (along a XY plane) is removed, and the remaining portion of the channel material layer 108m is considered as a channel layer 108A (may also be referred to as a semiconductor layer or a low dimension layer) underneath the insulating layer 110A. For example, the insulating layer 110A is interposed between and separates the source/drain regions 112 from the channel layer 118A. In some embodiments, the channel layer 108A has a thickness of about 0.3 nm to about 10 nm, as measured along the direction Z. In one embodiment, the channel layer 108A includes one or a few atomic layers of the low dimensional materials. Each atomic layer of the low dimensional materials may have a thickness of about 0.3 nm to about 1 nm. For example, the channel layer 108A includes one to ten atomic layers of the low dimensional materials. The channel layer 108A may include 1, 2, 3, 4, 5, 6, 7, 8, 9, or 10 atomic layers of the low dimensional materials. For example, the source/drain regions 112 are in the form of parallel strips extending in direction Y. Through the formation of the source/drain regions 112, the region of the channel layer 108A located between the source/drain regions 112 may function as the channel region CR (or may be referred to as an active channel region) of a transistor. On the other hand, the portions of the channel layer 108A located outside the source/drain regions 112 are electrically floated and functionally futile.

The removal process may include an etching process. In some embodiments, the etching process includes performing one or more anisotropic etching process(es), isotropic etching process(es) or a combination thereof. In some embodiments, the etching process may include performing a reactive ion etching process or an atomic layer etching process. In some embodiments, the etching process may include performing a reactive gas-assisted etching process or a metal-assisted chemical etching process. In some embodiments, the etching process may include performing a laser etching process and/or a thermal annealing process. During the etching process in the disclosure, it is able to remove one atomic layer at a time.

Alternatively, the source/drain regions 112 may be formed in the openings O formed in the photoresist pattern PR and on the insulating layer 110A by, but not limited to, forming a metallic material (not shown) over the photoresist pattern PR and filling up the openings O to form the source and drain regions 112. For example, an optional seed/liner material layer (not shown) may be formed covering the sidewalls and the bottoms of the openings O before forming the metallic material. In some embodiments, the metallic material includes one or more materials selected from titanium (Ti), chromium (Cr), tungsten (W), scandium (Sc), niobium (Nb), nickel (Ni), palladium (Pd), platinum (Pt), silver (Ag), gold (Au), aluminum (Al), ruthenium (Ru), molybdenum (Mo), tantalum (Ta), alloys thereof, and nitrides thereof, for example. In some embodiments, the metallic material includes titanium (Ti), chromium (Cr), tungsten (W), scandium (Sc), niobium (Nb), nickel (Ni), palladium (Pd), platinum (Pt), silver (Ag), gold (Au), aluminum (Al) or combinations thereof. In some embodiments, the metallic material is formed by CVD (such as metal organic CVD) or PVD (such as thermal evaporation). In some embodiments, the formation of the metallic material may include performing a plating process (such as electrochemical plating (ECP)). In some embodiments, the metallic material includes gold, palladium, titanium or gold formed by a metal organic CVD process.

In some embodiments, the seed/liner material is referred to as a metal layer, which can be a single layer or a composite layer comprising a plurality of sub-layers formed of different materials. In some embodiments, the seed/liner material include titanium, copper, molybdenum, tungsten, titanium nitride, titanium tungsten, combinations thereof, or the like. For example, the seed/liner material may include a titanium layer and a copper layer over the titanium layer. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The seed/liner material may be formed using, for example, sputtering, PVD, or the like. In some embodiments, the seed/liner material may be conformally formed on the photoresist pattern PR by sputtering, and in contact with the photoresist pattern PR and the insulating layer 110A exposed by the openings O formed in the photoresist pattern PR. In some embodiments, the extra seed/liner material and the extra metallic material may be removed by performing a planarization process, an etching process, or other suitable processes. In some embodiments, the planarization process may include performing a chemical mechanical polishing (CMP) process. As described above, owing to the position of the insulating layer 110A, the source/drain regions 112 and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 100A. That is, the Schottky barrier height can be greatly and effectively reduced, and the reliability of the semiconductor device 100A is ensured. In addition, by controlling a layer-number of the atomic layers constituting the channel layer 108A serving as the channel region CR, an effective channel width can be greatly improved while no change in the size of the footprint of the channel region CR in the semiconductor device 100A. For example, by increasing the layer-number of the atomic layers constituting the channel layer 108A serving as the channel region CR, the effective channel width of the semiconductor device 100A can be increased.

Continued on FIG. 7, in some embodiments, a dielectric material layer 114m is formed over the source/drain regions 112 and the channel layer 108A exposed by the source/drain regions 112. In some embodiments, the dielectric material layer 114m conformally covers the source/drain regions 112 and the channel layer 108A within the device region DR. In some embodiments, the material of the dielectric material layer 114m includes an oxide material such as hafnium oxide (e.g. HfO₂), aluminum oxide (e.g. Al₂O₃), or zirconium oxide (e.g. ZrO₂), or other suitable high-k dielectric material(s). It should be noted that the high-k dielectric materials are generally dielectric materials having a dielectric constant larger than 3.9, or greater than about 10, or greater than about 12, or even greater than about 16. For example, the high-k materials may include metal oxide, such as ZrO₂, Gd₂O₃, HfO₂, BaTiO₃, Al₂O₃, LaO₂, TiO₂, Ta₂O₅, Y₂O₃, STO, BTO, BaZrO, HfZrO, HfLaO, HfTaO, HfTiO, or a combination thereof. In some embodiments, the material of the dielectric material layer 114m includes hexagonal boron nitride (h-BN). For example, the dielectric material layer 114m may be formed by CVD such as HDP-CVD, SACVD, or ALD. In some embodiments, the dielectric material layer 114m has a thickness ranging from about 0.5 nm to about 15 nm.

Referring to FIG. 7 and FIG. 8 together, in some embodiments, after the dielectric material layer 114m is formed, a gate structure 116 is formed on the dielectric material layer 114m and between the source/drain regions 112. In some embodiments, the gate structure 116 is formed over the (active) channel region CR of the channel layer 108A. The gate structure 116 extends along the direction Y over the substrate, as shown in FIG. 8. For example, the gate structure 116 is a strip parallel to the source/drain regions 112. In some embodiments, after the gate structure 116 is formed, the extra dielectric material layer 114m located outside the gate structure 116 is removed and thus forms a dielectric layer 114. The remained dielectric material layer 114m (e.g., the dielectric layer 114) underlying the gate structure 116 functions as the gate dielectric layer. The gate structure 116 may be referred to as a gate of the transistor. In some embodiments, as seen in FIG. 8, within the device region CR defined by the isolation structures 103, the source/drain regions 112 and the gate structure 116 individually intersect with and cover the strip shaped patterns of the channel layer 108A. It is understood that the gate structure 116 may be separated/cut into different sections based on the design requirement of the device. In some embodiments, the gate structure 116 may be formed by blanketly forming a gate electrode material layer (not shown) and then patterning the gate electrode material layer into the strip shaped gate structure. In some embodiments, the gate structure 116 has a thickness ranging from about 1 nm to about 30 nm.

In some embodiments, the material of the gate structure 116 includes a metal or a metal alloy, or metal nitride. For example, in some embodiments, the material of the gate structure 116 includes Ti. Pt, Pd, Au, W, Ag, Ni, Al, TiN, tantalum nitride (TaN), tungsten nitride (WN), or combinations thereof. Moreover, the gate structure 116 may further include a liner layer, an interfacial layer, a work function layer, or a combination thereof. In some alternative embodiments, a seed layer, a barrier layer, an adhesion layer, or a combination thereof may also be included between the gate structure 116 and the channel layer 108A. In some embodiments, the gate structure 116 is formed by CVD (such as MOCVD) or PVD (such as thermal evaporation). In some embodiments, the formation of the gate structure 116 may include performing a plating process (such as ECP).

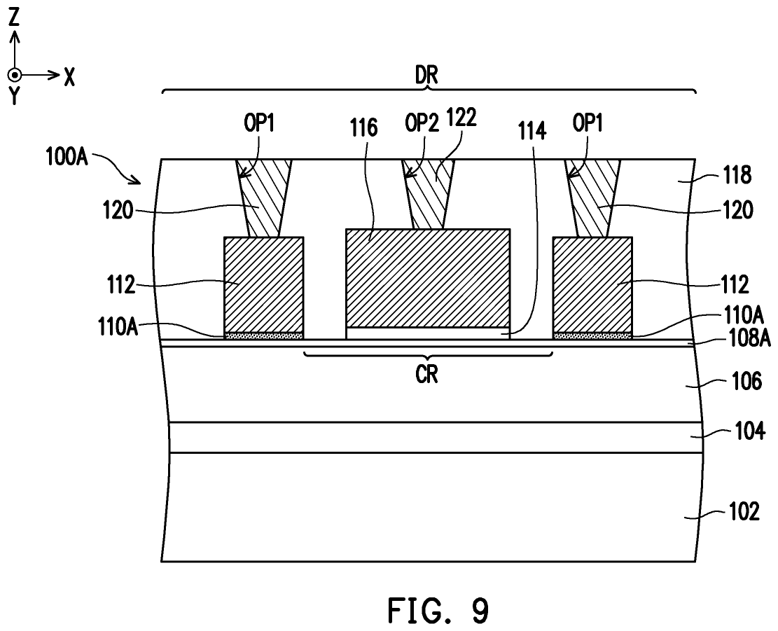

Referring to FIG. 9, in some embodiments, an interlayer dielectric (ILD) layer 118 is formed blanketly over the substrate 102, covering the channel layer 108A exposed by the source/region regions 112 and the gate structure 116. In some embodiments, the ILD layer 118 further covers the insulating layer 110A, the dielectric layer 114, the source/drain regions 112, and the gate structure 116. For example, the sidewalls of the insulating layer 110A, the dielectric layer 114, the source/drain regions 112, and the gate structure 116 are in contact with the ILD layer 118. In the case, the top surfaces of the source/drain regions 112, and the gate structure 116 are in contact with the ILD layer 118. In some embodiments, the material of the ILD layer 118 includes silicon oxide, silicon nitride, or one or more low-k dielectric materials. Examples of low-k dielectric materials include silicate glass such as phospho-silicate-glass (PSG) and boro-phospho-silicate-glass (BPSG), BLACK DIAMOND®, SILK®, hydrogen silsesquioxane (HSQ), fluorinated silicon oxide (SiOF), amorphous fluorinated carbon, parylene, BCB (bis-benzocyclobutene), flare, or a combination thereof. It is understood that the ILD layer 118 may include one or more dielectric materials or one or more dielectric layers. In some embodiments, the ILD layer 118 is formed to a suitable thickness by flowable CVD (FCVD), PECVD, HDPCVD, SACVD, spin-on coating, or other suitable methods. For example, an interlayer dielectric material layer (not shown) may be formed by PECVD and an etching or polishing process may be performed to reduce the thickness of the interlayer dielectric material layer until a desirable thickness to form the ILD layer 118.

Continued on FIG. 9, after forming the ILD layer 118, a plurality of contacts 120 and 122 are formed, and a transistor device 100A (e.g. FET device) is formed, in some embodiments. In some embodiments, the contacts 120 are formed in the ILD layer 118 at locations right above the source/drain regions 112, and the contact 122 (only one is shown) is formed in the ILD layer 118 at the location right above the gate structure 116. In some embodiments, the contacts 120 and 122 directly contact and are connected to the source/drain regions 112 and the gate structure 116 respectively.

In some embodiments, the formation of the contacts 120 and 122 includes forming a patterned mask layer (not shown) over the ILD layer 118, dry etching the ILD layer using the patterned mask layer as a mask to form contact openings OP1 exposing the source/drain regions 112 and a contact opening OP2 (only one is shown) exposing the gate structure 116. As seen in FIG. 9, the contact openings OP1, OP2 are shown with slant sidewalls, for example. It is understood that the contact openings may be formed with substantially vertical sidewalls if feasible, and the numbers of the contact openings OP1, OP2 are merely exemplary but not intended for limiting the scope of this disclosure. In some embodiments, the ILD layer 118 may further include an etch stop layer (not shown) therein for assisting the formation of the contact openings. Thereafter, a metallic material is deposited and filled into the contact openings OP1, OP2 to form the contacts 120 and 122. The metallic material includes Al, copper (Cu), W, cobalt (Co), alloys thereof or nitrides thereof, for example. In one embodiment, the metallic material is formed by performing a CVD process or a PVD process. Optionally, the extra metallic material may be removed by performing a planarization process, an etching process, or other suitable processes. In some embodiments, the planarization process may include performing a CMP process. As seen in FIG. 9, the top surface of the ILD layer 118 is substantially flush with and levelled with the top surfaces of the contacts 120 and 122. Up to here, the semiconductor device 100A is manufactured, where the semiconductor device 100A is referred to as a finFET.

As shown in FIG. 9, for example, the structure of the transistor device 100A includes the substrate 102, the overlay layer 104 disposed on the substrate 102, the semiconductor fin 106 and the channel layer 108A disposed on the overlay layer 104, the source/drain regions 112 and the insulating layer 110A disposed on the channel layer 108A, and the gate structure 116 and the dielectric layer 114 disposed on the channel layer 108A. In some embodiments, the semiconductive fin 106 is disposed between the channel layer 108A and the overlay layer 104. In the case, the insulating layer 110A is disposed between the source/drain regions 112 and the channel layer 108A, and the dielectric layer 114 is disposed between the gate structure 116 and the channel layer 108A. In some embodiments, the channel layer 108A located between the source/drain regions 112 and over the gate structure 116 functions as the channel region CR (channel layer) of the transistor, and the source/drain regions 112 are electrically connected (e.g. top-contacted) with the channel region CR (channel layer) of the transistor. In some embodiments, in the transistor device 100A, the dielectric layer 114 sandwiched between the gate structure 116 and the channel layer 108A is in contact with the channel region CR but is spaced apart from the source/drain regions 112. In some embodiments, the semiconductor device 100A includes the contacts 120 and 122 respectively in contact with the source/drain regions 112 and the gate structure 116. In some embodiments, the semiconductor device 100A further includes the ILD layer 118 to covering up the gate structure 116 and the source/drain regions 112 and at least laterally covering the contacts 120 and 122.

In the illustrated embodiments, the described methods and structures may be formed compatible with the current semiconductor manufacturing processes. In exemplary embodiments, the described methods and structures are formed during front-end-of-line (FEOL) processes. In one embodiment, the transistor device 100A is a logic device. In some embodiments, the material of the channel material layer 108m includes TMD and the transistor device 100A is a TMD-based fin field-effect transistor (TMD-finFET).

The illustrated structure of transistor device 100A may be a portion of integrated circuits. In some embodiments, the illustrated structure may include active devices such as thin film transistors, high voltage transistors, passive components, such as resistors, capacitors, inductors, fuses, and/or other suitable components. In some embodiments, additional steps may be provided before, during, and after the process steps depicted from FIG. 1 to FIG. 9, and some of the steps described above may be replaced or eliminated, for additional embodiments of the method.

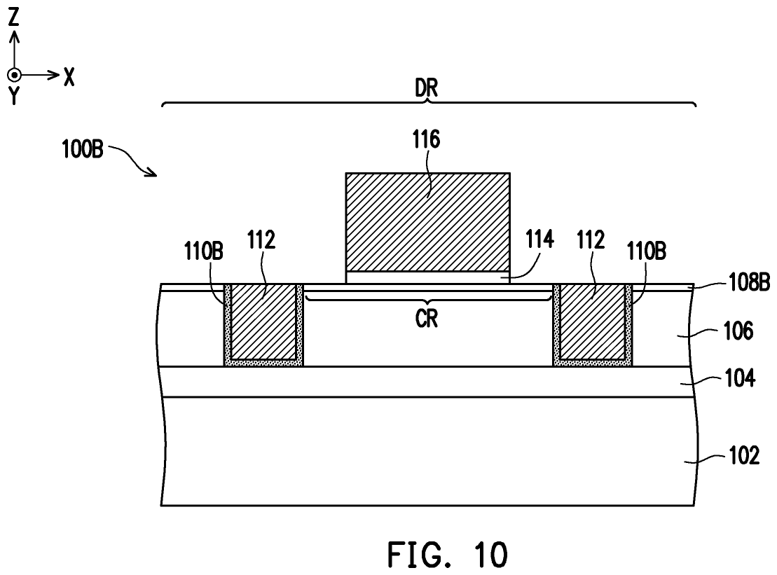

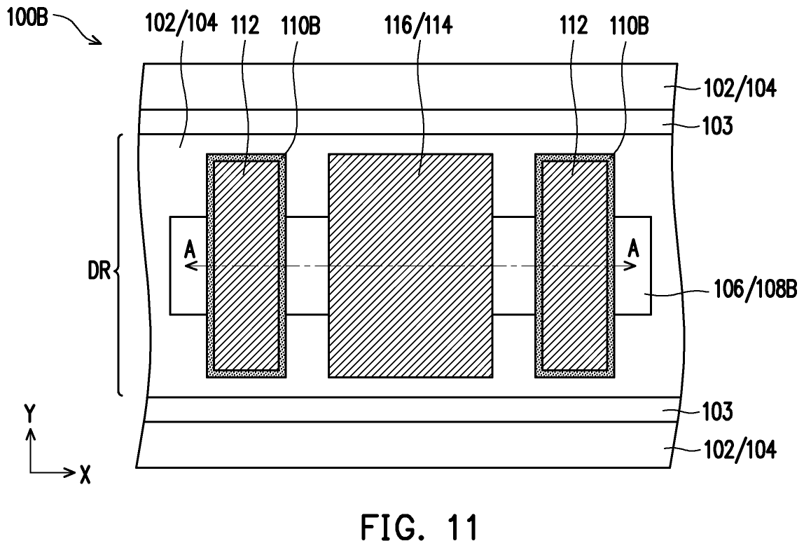

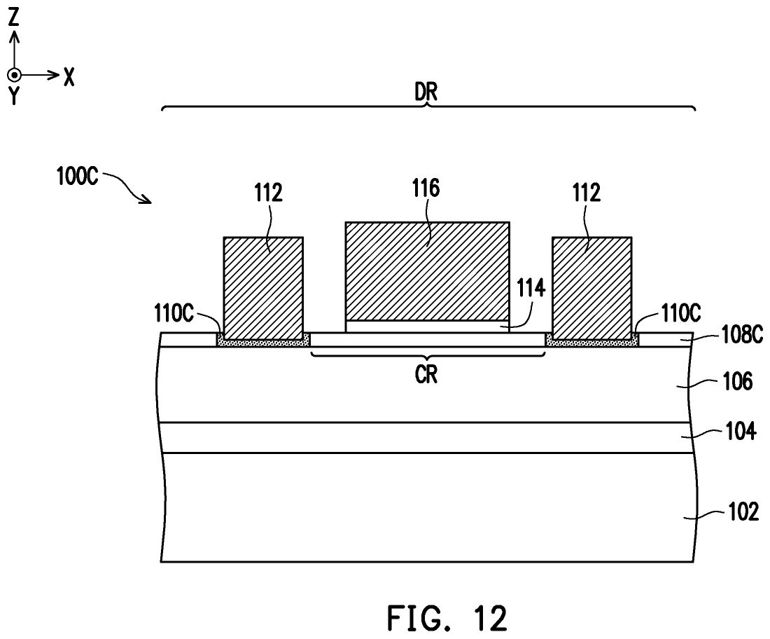

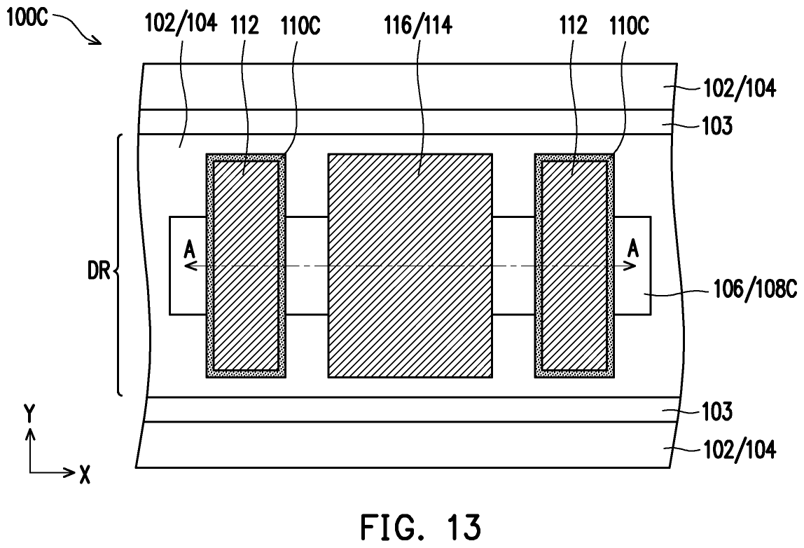

FIG. 10 and FIG. 11 are schematic views showing a semiconductor device 100B in accordance with alternative embodiments of the disclosure. FIG. 12 and FIG. 13 are schematic views showing a semiconductor device 100C in accordance with alternative embodiments of the disclosure. The exemplary structures shown in FIGS. 10-11 and FIGS. 12-13 may be fabricated following the process steps as described in the embodiments as shown from FIG. 1 to FIG. 9, and similar materials may be used as described in the previous embodiments may be used. However, it is understood that any other compatible process steps or methods or any other suitable materials may be utilized and comprehensible modifications or adjustments may be made for forming the exemplary structure of this disclosure.

Referring to FIG. 10 and FIG. 11, in some embodiments, the semiconductor device 100B includes a substrate 102, an overlay layer 104 disposed on the substrate 102, a semiconductor fin 106 disposed on the overlayer layer 104, a channel layer 108B disposed on the semiconductor fin 106, source/drain regions 112 and an insulating layer 110B disposed over the substrate 102 and on the overlay layer 104, and a gate structure 116 and a dielectric layer 114 disposed over the substrate 102 and on the channel layer 108B. For example, a plurality of through openings (not labeled) are formed in (e.g., penetrate through) the channel layer 108B and the semiconductor fin 106 to expose portions of the overlay layer 104, where the insulating layer 110B are formed to line the sidewalls and bottoms of the through openings and in contact with the exposed portions of the overlayer layer 104, and the source/drain regions 112 fill up the through openings. In the case, the source/drain regions 112 are separated from the semiconductor fin 106 and the channel layer 108B by the insulating layer 110B. In some embodiments, top surfaces of the source/drain regions 112 are substantially flush with and levelled with a top surface of the channel layer 108B. For example, the top surfaces of the source/drain regions 112 are substantially coplanar to the top surface of the channel layer 108B, as shown in FIG. 10. In some embodiments, the source/drain regions 112 and the insulating layer 110B penetrate through the semiconductor fin 106 and the channel layer 108B, and the insulating layer 110B surrounds the sidewalls and bottom surfaces of the source/drain regions 112 to separate the source/drain regions 112 from the overlayer layer 104, the semiconductor fin 106 and the channel layer 108B. In some embodiments, the dielectric layer 114 is disposed between the gate structure 116 and the channel layer 108B, and the gate structure 116 is separated from the channel layer 108B by the dielectric layer 114 and is separated from the source/drain regions 112 by gaps. In the case, the region of the channel layer 108B located between the source/drain regions 112 and over the gate structure 116 may function as the channel region CR (or may be referred to as an active channel region) of a transistor, as shown in FIG. 10. On the other hand, the portions of the channel layer 108B located outside the source/drain regions 112 are electrically floated and functionally futile. As described above, owing to the position of the insulating layer 110B, the source/drain regions 112 and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 100B. That is, the Schottky barrier height can be greatly and effectively reduced, and the reliability of the semiconductor device 100B is ensured. In addition, by controlling a layer-number of the atomic layers constituting the channel layer 108B serving as the channel region CR, an effective channel width can be greatly improved while no change in the size of the footprint of the channel region CR in the semiconductor device 100B. For example, by increasing the layer-number of the atomic layers constituting the channel layer 108B serving as the channel region CR, the effective channel width of the semiconductor device 100B can be increased. Also, since the source/drain regions 112 are edge-contacted with the channel layer 108B, clear Fermi level de-pinning effect is achieved and the current injection efficiency of the semiconductor device 100B is improved.

As shown in FIG. 11, in some embodiments, the semiconductor fin 106 and the channel layer 108B extending along the direction X and the source/drain regions 112 and the gate structure 116 extending along the direction Y are formed on the substrate 102 within the device region DR along the direction Z. It is understood that isolation structures 103 may be included in the substrate 102 and the device region DR may be defined through the arrangement of the isolation structures 103. As shown in FIG. 10 and FIG. 11, the insulating layer 110B surrounds the sidewalls of the source/drain regions 112, where the channel layer 108B located between the source/drain regions 112 and over the gate structure 116 functions as the channel region CR (channel layer) of the transistor, and the source/drain regions 112 are electrically connected (e.g. edge-contacted) with the channel region CR (channel layer) of the transistor. In some embodiments, the semiconductor device 100B further includes contacts 120 and 122 (not shown in FIG. 10 and FIG. 11) respectively in contact with the source/drain regions 112 and the gate structure 116. In some embodiments, the semiconductor device 100B further includes the ILD layer 118 (not shown in FIG. 10 and FIG. 11) to covering up the gate structure 116 and the source/drain regions 112 and at least laterally covering the contacts 120 and 122.

In some embodiments, the channel layer 108B has a thickness of about 0.3 nm to about 10 nm, as measured along the direction Z. In one embodiment, the channel layer 108B includes one or a few atomic layers of the low dimensional materials. Each atomic layer of the low dimensional materials may have a thickness of about 0.3 nm to about 1 nm. For example, the channel layer 108B includes one to ten atomic layers of the low dimensional materials. The channel layer 108B may include 1, 2, 3, 4, 5, 6, 7, 8, 9, or 10 atomic layers of the low dimensional materials. The insulating layer 110B may have a thickness of about 0.5 nm to about 3 nm, as measured along the direction Z. The details of the substrate 102, the isolation structure 103, the overlay layer 104, the semiconductor fin 106, the source/drain regions 112, the dielectric layer 114, the gate structure 116, the contacts 120, 122, and the ILD layer 118 are previously described in FIG. 1 through FIG. 9, and thus are not repeated herein. In addition, the formation and material of the channel layer 108B are similar to or substantially identical to the formation and material of the channel layer 108A as described in FIG. 2 through FIG. 8, the formation and material of the insulating layer 110B are similar to or substantially identical to the formation and material of the insulating layer 110A as described in FIG. 5, and thus are not repeated herein.

For example, the formations of the channel 108B and the insulating layer 110B may include, but not limited to, forming a channel material layer (not shown) over the substrate 102 covering the whole device region DR of the substrate 102 or providing a channel material layer (not shown) with a pattern over the substrate 102 covering a portion of the device region DR of the substrate 102 (such as covering the portion of the device region DR where the semiconductor fin 106 disposed at), where the semiconductor fin 106 is covered by the channel material layer; patterning the channel material layer to form the through openings (not shown) in the channel material layer so to form the channel layer 108B, where the through openings further extends into the semiconductor fin 106 and thus the overlay layer 104 are partially exposed by the through openings; conformally forming another channel material layer (not shown) over the substrate 102 covering the whole device region DR of the substrate 102 or providing another channel material layer (not shown) with a pattern over the substrate 102 conformally covering a portion of the device region DR of the substrate 102 (such as covering the portion of the device region DR where the semiconductor fin 106 disposed at), where the channel material layer is covered by the another channel material layer; performing an oxidation process to convert the another channel material layer inside the through openings into the insulating layer 110B (similar to the process as described in FIG. 5); filling a conductive material into the through openings to form the source/drain regions 112, where the sidewalls and bottoms of the source/drain regions 112 are in contact with the insulating layer 110B; and removing portions of the another channel material layer outside of the through openings to accessibly reveal the channel layer 108B. The formation and material of the channel material layer and/or the another channel material layer may be similar to or substantially identical to the formation and material of the channel material layer 118m as described in FIG. 2, the formation and material of the conductive material may be similar to or substantially identical to the formation and material of the conductive material layer 112m as described in FIG. 6, and thus are not repeated herein.

However, the disclosure is not limited thereto; alternatively, the formations of the channel 108B and the insulating layer 110B may include, but not limited to, forming a channel material layer (not shown) over the substrate 102 covering the whole device region DR of the substrate 102 or providing a channel material layer (not shown) with a pattern over the substrate 102 covering a portion of the device region DR of the substrate 102 (such as covering the portion of the device region DR where the semiconductor fin 106 disposed at), where the semiconductor fin 106 is covered by the channel material layer; patterning the channel material layer to form the through openings (not shown) in the channel material layer so to form the channel layer 108B, where the through openings further extends into the semiconductor fin 106 and thus the overlay layer 104 are partially exposed by the through openings; filling a conductive material into the through openings; forming a self-limiting oxidation process to the conductive material to form a layer of insulating material (e.g., the insulating layer 110B) at an outermost surface of the conductive material so to form the source/drain regions 112, where the sidewalls and bottoms of the source/drain regions 112 are in contact with the insulating layer 110B. The formation and material of the channel material layer may be similar to or substantially identical to the formation and material of the channel material layer 118m as described in FIG. 2, the formation and material of the conductive material may be similar to or substantially identical to the formation and material of the conductive material layer 112m as described in FIG. 6, and thus are not repeated herein.

Referring to FIG. 12 and FIG. 13, in some embodiments, the semiconductor device 100C includes a substrate 102, an overlay layer 104 disposed on the substrate 102, a semiconductor fin 106 disposed on the overlayer layer 104, a channel layer 108C disposed on the semiconductor fin 106, source/drain regions 112 and an insulating layer 110C disposed over the substrate 102 and on the semiconductor fin 106, and a gate structure 116 and a dielectric layer 114 disposed over the substrate 102 and on the channel layer 108C. For example, a plurality of through openings (not labeled) are formed in (e.g., penetrate through) the channel layer 108C to expose portions of the semiconductor fin 106, where the insulating layer 110C are formed to line the sidewalls and bottoms of the through openings and in contact with the exposed portions of the semiconductor fin 106, and the source/drain regions 112 fill up the through openings. In the case, the source/drain regions 112 are separated from the semiconductor fin 106 and the channel layer 108C by the insulating layer 110C. In some embodiments, top surfaces of the source/drain regions 112 are over (e.g., above) a top surface of the channel layer 108C. For example, the top surfaces of the source/drain regions 112 are not flush with the top surface of the channel layer 108C, as shown in FIG. 12. In some embodiments, the source/drain regions 112 and the insulating layer 110C penetrate through the channel layer 108C, and the insulating layer 110C partially surrounds the sidewalls and completely covers bottom surfaces of the source/drain regions 112 to separate the source/drain regions 112 from the semiconductor fin 106 and the channel layer 108C. In some embodiments, the dielectric layer 114 is disposed between the gate structure 116 and the channel layer 108C, and the gate structure 116 is separated from the channel layer 108C by the dielectric layer 114 and is separated from the source/drain regions 112 by gaps. In the case, the region of the channel layer 108C located between the source/drain regions 112 and over the gate structure 116 may function as the channel region CR (or may be referred to as an active channel region) of a transistor, as shown in FIG. 12. On the other hand, the portions of the channel layer 108C located outside the source/drain regions 112 are electrically floated and functionally futile.

As shown in FIG. 13, in some embodiments, the semiconductor fin 106 and the channel layer 108C extending along the direction X and the source/drain regions 112 and the gate structure 116 extending along the direction Y are formed on the substrate 102 within the device region DR along the direction Z. It is understood that isolation structures 103 may be included in the substrate 102 and the device region DR may be defined through the arrangement of the isolation structures 103. As shown in FIG. 12 and FIG. 13, the insulating layer 110C surrounds the sidewalls of the source/drain regions 112, where the channel layer 108C located between the source/drain regions 112 and over the gate structure 116 functions as the channel region CR (channel layer) of the transistor, and the source/drain regions 112 are electrically connected (e.g. edge-contacted) with the channel region CR (channel layer) of the transistor. In some embodiments, the semiconductor device 100C further includes contacts 120 and 122 (not shown in FIG. 12 and FIG. 13) respectively in contact with the source/drain regions 112 and the gate structure 116. In some embodiments, the semiconductor device 100C further includes the ILD layer 118 (not shown in FIG. 12 and FIG. 13) to covering up the gate structure 116 and the source/drain regions 112 and at least laterally covering the contacts 120 and 122.

In some embodiments, the channel layer 108C has a thickness of about 0.3 nm to about 10 nm, as measured along the direction Z. In one embodiment, the channel layer 108C includes one or a few atomic layers of the low dimensional materials. Each atomic layer of the low dimensional materials may have a thickness of about 0.3 nm to about 1 nm. For example, the channel layer 108C includes one to ten atomic layers of the low dimensional materials. The channel layer 108C may include 1, 2, 3, 4, 5, 6, 7, 8, 9, or 10 atomic layers of the low dimensional materials. The insulating layer 110C may have a thickness of about 0.5 nm to about 3 nm, as measured along the direction Z. The details of the substrate 102, the isolation structure 103, the overlay layer 104, the semiconductor fin 106, the source/drain regions 112, the dielectric layer 114, the gate structure 116, the contacts 120, 122, and the ILD layer 118 are previously described in FIG. 1 through FIG. 9, and thus are not repeated herein. In addition, the formation and material of the channel layer 108C are similar to or substantially identical to the formation and material of the channel layer 108B as described in FIG. 10 and FIG. 11, the formation and material of the insulating layer 110C are similar to or substantially identical to the formation and material of the insulating layer 110A as described in FIG. 2 through FIG. 8 (e.g., where an additional two-dimensional material layer is conformally formed in the channel layer 108C, portions of the additional two-dimensional material layer is converted into the insulating layer 110C inside the openings formed in the channel layer 108C, and the rest of the additional two-dimensional material layer outside the openings formed in the channel layer 108C is removed), and thus are not repeated herein. In alternative embodiments (not shown), the insulating layer 110C may be formed by performing self-limiting oxidation to the source/drain regions 112 disposed in the openings formed in the channel layer 108C, where the source/drain regions 112 is completely covered by the insulating layer 110C. As described above, owing to the position of the insulating layer 110C, the source/drain regions 112 and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 100C. That is, the Schottky barrier height can be greatly and effectively reduced, and the reliability of the semiconductor device 100C is ensured. In addition, by controlling a layer-number of the atomic layers constituting the channel layer 108B serving as the channel region CR, an effective channel width can be greatly improved while no change in the size of the footprint of the channel region CR in the semiconductor device 100C. For example, by increasing the layer-number of the atomic layers constituting the channel layer 108C serving as the channel region CR, the effective channel width of the semiconductor device 100C can be increased. Also, since the source/drain regions 112 are edge-contacted with the channel layer 108C, clear Fermi level de-pinning effect is achieved and the current injection efficiency of the semiconductor device 100C is improved.

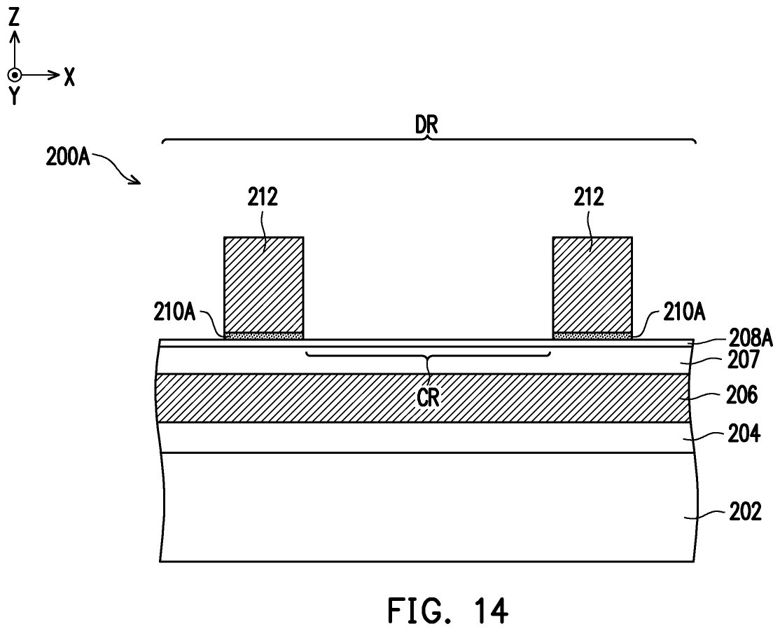

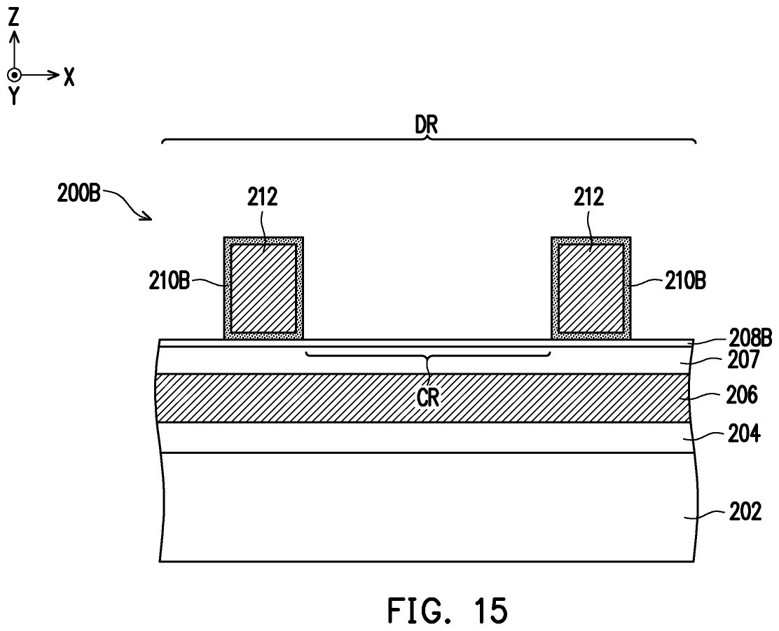

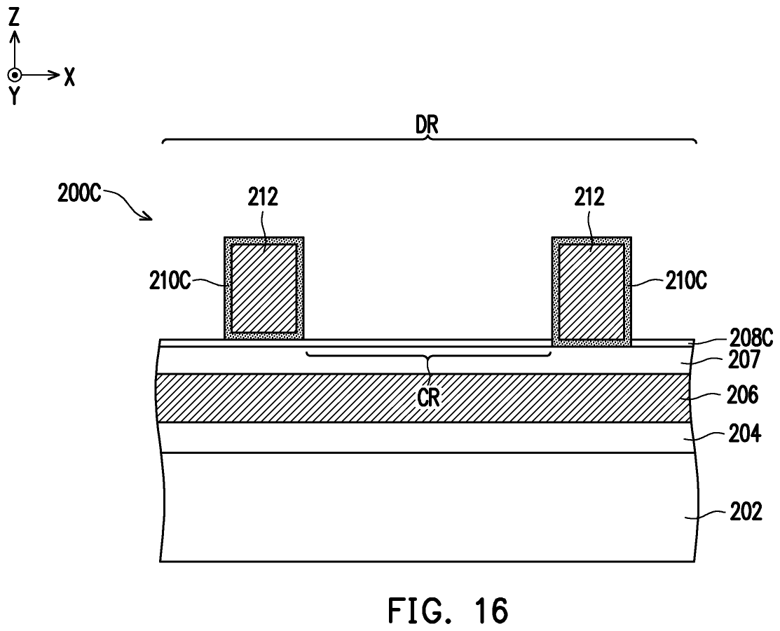

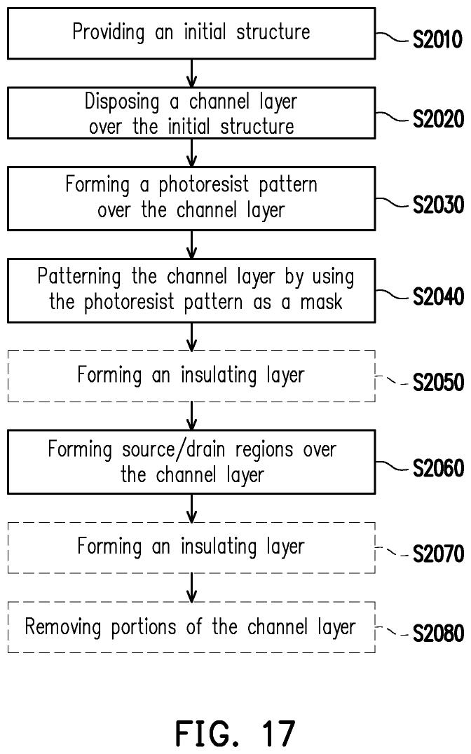

FIG. 14 is a schematic cross-sectional view showing a semiconductor device in accordance with some embodiments of the disclosure. FIG. 15 and FIG. 16 are schematic cross-sectional views showing a semiconductor device in accordance with alternative embodiments of the disclosure. The exemplary structures shown in FIG. 15 and FIG. 16 may be fabricated following the process steps as described in the embodiments as shown from FIG. 1 to FIG. 9 and/or FIG. 14, and similar materials may be used as described in the previous embodiments may be used. However, it is understood that any other compatible process steps or methods or any other suitable materials may be utilized and comprehensible modifications or adjustments may be made for forming the exemplary structure of this disclosure. FIG. 17 is a flow chart illustrating a method for manufacturing a semiconductor device in accordance with some embodiments of the disclosure.

Referring to FIG. 14, in some embodiments, a semiconductor device 200A includes a substrate 202, an overlay layer 204 disposed on the substrate 202, a gate structure 206 disposed on the overlayer layer 204, a dielectric layer 207 disposed on the gate structure 206, a channel layer 208A disposed on the dielectric layer 207, an insulating layer 210A disposed on the dielectric layer 207, and source/drain regions 212 disposed on the insulating layer 210A. As shown in FIG. 14, the insulating layer 210A may be disposed between the source/drain regions 212 and the dielectric layer 207, and may separate the source/drain regions 212 from the channel layer 208A. In the case, the region of the channel layer 208A located between the source/drain regions 212 and over the gate structure 206 may function as a channel region CR (or may be referred to as an active channel region) of a transistor, as shown in FIG. 14. In some embodiments, the source/drain regions 212 are electrically connected (e.g. top-contacted) with the channel region CR (channel layer) of the transistor. On the other hand, the portions of the channel layer 208A located outside the source/drain regions 212 are electrically floated and functionally futile. For example, the gate structure 206 is separated from the channel layer 208A by the dielectric layer 207, where the source/drain regions 212 are disposed over the gate structure 206. The dielectric layer 207 may be referred to as a gate dielectric layer of the transistor, and the gate structure 206 may be referred to as a gate of the transistor. In some embodiments, the semiconductor device 200A is referred to as a bottom-gated planar FET. As described above, owing to the position of the insulating layer 210A, the source/drain regions 212 and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 200A. That is, the Schottky barrier height can be greatly and effectively reduced, and the reliability of the semiconductor device 200A is ensured. In some embodiments, the semiconductor device 200A further includes contacts (not shown in FIG. 14) respectively in contact with the source/drain regions 212 and the gate structure 206. In some embodiments, the semiconductor device 200A further includes the ILD layer (not shown in FIG. 14) to covering up the source/drain regions 212 and at least laterally covering the contacts.

In some embodiments, the channel layer 208A has a thickness of about 0.3 nm to about 10 nm, as measured along the direction Z. In one embodiment, the channel layer 208A includes one or a few atomic layers of the low dimensional materials. Each atomic layer of the low dimensional materials may have a thickness of about 0.3 nm to about 1 nm. For example, the channel layer 208A includes one to ten atomic layers of the low dimensional materials. The channel layer 208A may include 1, 2, 3, 4, 5, 6, 7, 8, 9, or 10 atomic layers of the low dimensional materials. The insulating layer 210A may have a thickness of about 0.5 nm to about 3 nm, as measured along the direction Z. The details of each of the substrate 202, the overlay layer 204, the gate structure 206, the dielectric layer 207, the channel layer 208A, the insulating layer 210A, the source/drain regions 212, the contacts, and the ILD layer are respectively similar to or substantially identical to the details of each of the substrate 102, the overlay layer 104, the gate structure 116, the dielectric layer 114, the channel layer 108A, the insulating layer 110A, the source/drain regions 112, the contacts 120, 122, and the ILD layer 118 as previously described in FIG. 1 through FIG. 9, and thus are not repeated herein.

For one non-limiting example, the formation of the semiconductor device 200A includes, but not limited to, providing an initial structure (step S2010 of FIG. 17), where the initial structure includes a substrate, an overlay layer disposed on the substrate, a gate structure disposed on the overlay layer, and a dielectric layer disposed on the gate structure; forming a channel layer over the initial structure (step S2020 of FIG. 17, similar to process of FIG. 2 and FIG. 3), where the channel layer is disposed on (e.g., in contact with) the dielectric layer, and the dielectric layer is interposed between the channel layer and the gate structure; forming a photoresist pattern over the channel layer (step S2030 of FIG. 17, similar to process of FIG. 4), where the photoresist layer includes a plurality of openings exposing the channel layer; forming an insulating layer (step S2050 of FIG. 17, similar to process of FIG. 5) by performing an oxidation process onto the channel layer so to converting the exposed portions of the channel layer (by the openings) into the insulating layer; forming source/drain regions over the channel layer (step S2060 of FIG. 17, similar to process of FIG. 6 and FIG. 7), where the source/drain regions are separated from the channel layer by the insulating layer; and removing portions of the channel layer (step S2080 of FIG. 17, similar to process of FIG. 7) being laterally next to the insulating layer. Prior to the removal of the portions of the channel layer, the photoresist pattern is removed, in some embodiments.

Referring to FIG. 15, in some embodiments, a semiconductor device 200B includes a substrate 202, an overlay layer 204 disposed on the substrate 202, a gate structure 206 disposed on the overlayer layer 204, a dielectric layer 207 disposed on the gate structure 206, a channel layer 208B disposed on the dielectric layer 207, an insulating layer 210B disposed on the dielectric layer 207, and source/drain regions 212 disposed on the insulating layer 210B. As shown in FIG. 15, the insulating layer 210B may be disposed between the source/drain regions 212 and the dielectric layer 207, and may separate the source/drain regions 212 from the channel layer 208B. As shown in FIG. 15, the insulating layer 210B may completely surround the outermost surface of the source/drain regions 212, where the top surface, the bottom surface and the sidewalls connecting the top surface and the bottom surface of each of the source/drain regions 212 may be completely covered by the insulating layer 210B. In the case, the region of the channel layer 208B located between the source/drain regions 212 and over the gate structure 206 may function as a channel region CR (or may be referred to as an active channel region) of a transistor, as shown in FIG. 15. In some embodiments, the source/drain regions 212 are electrically connected (e.g. top-contacted) with the channel region CR (channel layer) of the transistor. On the other hand, the portions of the channel layer 208B located outside the source/drain regions 212 are electrically floated and functionally futile. For example, the gate structure 206 is separated from the channel layer 208B by the dielectric layer 207, where the source/drain regions 212 are disposed over the gate structure 206. The dielectric layer 207 may be referred to as a gate dielectric layer of the transistor, and the gate structure 206 may be referred to as a gate of the transistor. In some embodiments, the semiconductor device 200B is referred to as a bottom-gated planar FET. As described above, owing to the position of the insulating layer 210B, the source/drain regions 212 and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 200B. That is, the Schottky barrier height can be greatly and effectively reduced, and the reliability of the semiconductor device 200B is ensured. In some embodiments, the semiconductor device 200B further includes contacts (not shown in FIG. 15) respectively in contact with the source/drain regions 212 and the gate structure 206. In some embodiments, the semiconductor device 200B further includes the ILD layer (not shown in FIG. 15) to covering up the source/drain regions 212 and at least laterally covering the contacts.

In some embodiments, the channel layer 208B has a thickness of about 0.3 nm to about 10 nm, as measured along the direction Z. In one embodiment, the channel layer 208B includes one or a few atomic layers of the low dimensional materials. Each atomic layer of the low dimensional materials may have a thickness of about 0.3 nm to about 1 nm. For example, the channel layer 208B includes one to ten atomic layers of the low dimensional materials. The channel layer 208B may include 1, 2, 3, 4, 5, 6, 7, 8, 9, or 10 atomic layers of the low dimensional materials. The insulating layer 210B may have a thickness of about 0.5 nm to about 3 nm, as measured along the direction Z. The details of the substrate 202, the overlay layer 204, the gate structure 206, the dielectric layer 207, the channel layer 208B, the insulating layer 210B, the source/drain regions 212, the contacts, and the ILD layer are respectively similar to or substantially identical to the details of the substrate 102, the overlay layer 104, the gate structure 116, the dielectric layer 114, the channel layer 108A, the insulating layer 110A, the source/drain regions 112, the contacts 120, 122, and the ILD layer 118 as previously described in FIG. 1 through FIG. 9, and thus are not repeated herein.

For one non-limiting example, the formation of the semiconductor device 200B includes, but not limited to, providing an initial structure (step S2010 of FIG. 17), where the initial structure includes a substrate, an overlay layer disposed on the substrate, a gate structure disposed on the overlay layer, and a dielectric layer disposed on the gate structure; forming a channel layer over the initial structure (step S2020 of FIG. 17, similar to process of FIG. 2 and FIG. 3), where the channel layer is disposed on (e.g., in contact with) the dielectric layer, and the dielectric layer is interposed between the channel layer and the gate structure; forming a photoresist pattern over the channel layer (step S2030 of FIG. 17, similar to process of FIG. 4), where the photoresist layer includes a plurality of openings exposing the channel layer; forming source/drain regions over the channel layer (step S2060 of FIG. 17, similar to process of FIG. 6 and FIG. 7); and forming an insulating layer (step S2070 of FIG. 17, similar to process of FIGS. 10-11 and/or FIGS. 12-13) by performing an self-limiting oxidation process onto the source/drain regions so to converting the outermost portion of the source/drain regions into the insulating layer, where the source/drain regions are separated from the channel layer by the insulating layer. After the formation of the insulating layer, the photoresist pattern is removed, in some embodiments.

Referring to FIG. 16, in some embodiments, a semiconductor device 200C includes a substrate 202, an overlay layer 204 disposed on the substrate 202, a gate structure 206 disposed on the overlayer layer 204, a dielectric layer 207 disposed on the gate structure 206, a channel layer 208C disposed on the dielectric layer 207, an insulating layer 210C disposed on the dielectric layer 207 and penetrating through the channel layer 208C, and source/drain regions 212 disposed on the insulating layer 210C. As shown in FIG. 16, the insulating layer 210C may be disposed between the source/drain regions 212 and the dielectric layer 207, and may separate the source/drain regions 212 from the channel layer 208C. As shown in FIG. 16, the insulating layer 210C may completely surround the outermost surface of the source/drain regions 212, where the top surface, the bottom surface and the sidewalls connecting the top surface and the bottom surface of each of the source/drain regions 212 may be completely covered by the insulating layer 210C. In the case, the region of the channel layer 208C located between the source/drain regions 212 and over the gate structure 206 may function as a channel region CR (or may be referred to as an active channel region) of a transistor, as shown in FIG. 16. In some embodiments, the source/drain regions 212 are electrically connected (e.g. edge-contacted) with the channel region CR (channel layer) of the transistor. On the other hand, the portions of the channel layer 208C located outside the source/drain regions 212 are electrically floated and functionally futile. For example, the gate structure 206 is separated from the channel layer 208C by the dielectric layer 207, where the source/drain regions 212 are disposed over the gate structure 206. The dielectric layer 207 may be referred to as a gate dielectric layer of the transistor, and the gate structure 206 may be referred to as a gate of the transistor. In some embodiments, the semiconductor device 200C is referred to as a bottom-gated planar FET. As described above, owing to the position of the insulating layer 210C, the source/drain regions 212 and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 200C. That is, the Schottky barrier height can be greatly and effectively reduced, and the reliability of the semiconductor device 200C is ensured. Also, since the source/drain regions 212 are edge-contacted with the channel layer 208C, clear Fermi level de-pinning effect is achieved and the current injection efficiency of the semiconductor device 200C is improved. In some embodiments, the semiconductor device 200C further includes contacts (not shown in FIG. 16) respectively in contact with the source/drain regions 212 and the gate structure 206. In some embodiments, the semiconductor device 200C further includes the ILD layer (not shown in FIG. 16) to covering up the source/drain regions 212 and at least laterally covering the contacts.

In some embodiments, the channel layer 208C has a thickness of about 0.3 nm to about 10 nm, as measured along the direction Z. In one embodiment, the channel layer 208C includes one or a few atomic layers of the low dimensional materials. Each atomic layer of the low dimensional materials may have a thickness of about 0.3 nm to about 1 nm. For example, the channel layer 208C includes one to ten atomic layers of the low dimensional materials. The channel layer 208C may include 1, 2, 3, 4, 5, 6, 7, 8, 9, or 10 atomic layers of the low dimensional materials. The insulating layer 210C may have a thickness of about 0.5 nm to about 3 nm, as measured along the direction Z. The details of the substrate 202, the overlay layer 204, the gate structure 206, the dielectric layer 207, the channel layer 208C, the insulating layer 210C, the source/drain regions 212, the contacts, and the ILD layer are respectively similar to or substantially identical to the details of the substrate 102, the overlay layer 104, the gate structure 116, the dielectric layer 114, the channel layer 108A, the insulating layer 110A, the source/drain regions 112, the contacts 120, 122, and the ILD layer 118 as previously described in FIG. 1 through FIG. 9, and thus are not repeated herein.

For one non-limiting example, the formation of the semiconductor device 200C includes, but not limited to, providing an initial structure (step S2010 of FIG. 17), where the initial structure includes a substrate, an overlay layer disposed on the substrate, a gate structure disposed on the overlay layer, and a dielectric layer disposed on the gate structure; forming a channel layer over the initial structure (step S2020 of FIG. 17, similar to process of FIG. 2 and FIG. 3), where the channel layer is disposed on (e.g., in contact with) the dielectric layer, and the dielectric layer is interposed between the channel layer and the gate structure; forming a photoresist pattern over the channel layer (step S2030 of FIG. 17, similar to process of FIG. 4), where the photoresist layer includes a plurality of openings exposing the channel layer; patterning the channel layer by using the photoresist pattern as a mask (step 2040 of FIG. 17, similar to process of FIGS. 10-11 and/or FIGS. 12-13), where the dielectric layer is exposed by the channel layer with a plurality of openings penetrating therethrough; forming source/drain regions over the channel layer (step S2060 of FIG. 17, similar to process of FIG. 6 and FIG. 7), where the source/drain regions are disposed in the openings formed in the channel layer; and forming an insulating layer (step S2070 of FIG. 17, similar to process of FIGS. 10-11 and/or FIGS. 12-13) by performing an self-limiting oxidation process onto the source/drain regions so to converting the outermost portion of the source/drain regions into the insulating layer, where the source/drain regions are separated from the channel layer by the insulating layer. After the formation of the insulating layer, the photoresist pattern is removed, in some embodiments.

However, the disclosure is not limited thereto; alternatively, in a semiconductor device similar to the semiconductor device 200C, one of differences is that, the insulating layer may penetrate through the channel layer but not completely covering the source/drain regions. For example, in the semiconductor device similar to the semiconductor device 200C, the insulating layer penetrates through the channel layer and is only disposed between (e.g., directly sandwiched between) the source/drain regions and the channel layer.

It is understood that a plurality of isolation structures (not shown) may be included in the substrate 202 so to define one or multiple device region DR through the arrangement of the isolation structures, in the above embodiments of FIG. 14 through FIG. 16. The details of the isolation structures may be similar to or substantially identical to the details of the isolation structures 103 as previously described in FIG. 1 through FIG. 9, and thus are not repeated herein for simplicity.

In addition, in the above embodiments, the semiconductor devices 200A, 200B, 200C each are the bottom-gated planar FET. However, the disclosure is not limited thereto; alternatively, a semiconductor device may be top-gated planar FET, where the semiconductor device includes a gate structure disposed over a surface of the channel layer where the source/drain regions disposed at and between the source/drain regions, instead of the gate structure 206. In such case, the gate structure is separated from the channel layer by a gate dielectric layer. In an further alternative embodiment, a semiconductor device may be dual-gated planar FET, where the semiconductor device includes an additional gate structure disposed over a surface of the channel layer where the source/drain regions disposed at and between the source/drain regions. In such case, the additional gate structure is separated from the channel layer by an additional gate dielectric layer, and the gate structure 206 and the additional gate structure are overlapped with each other in the direction Z.

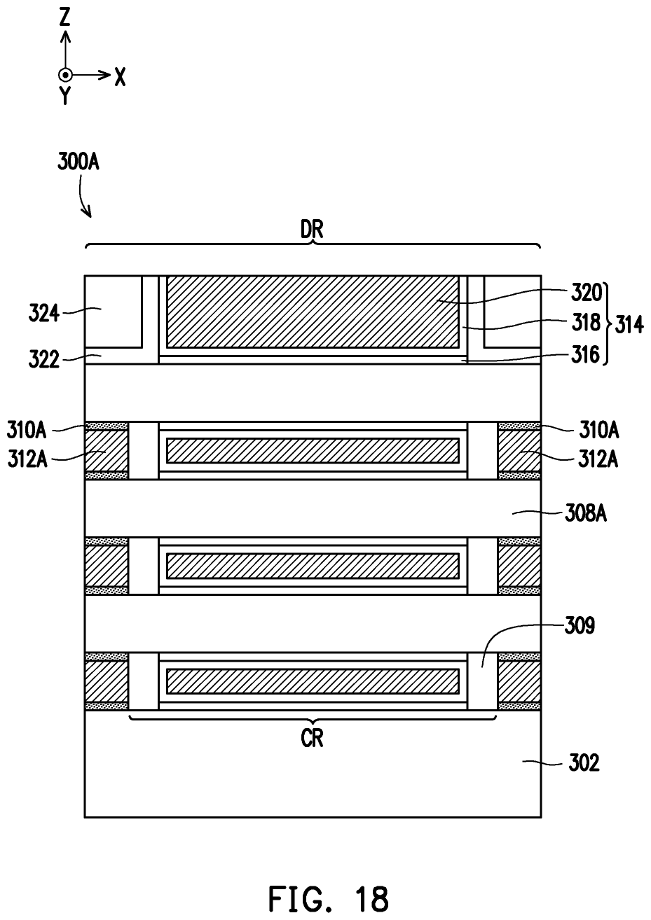

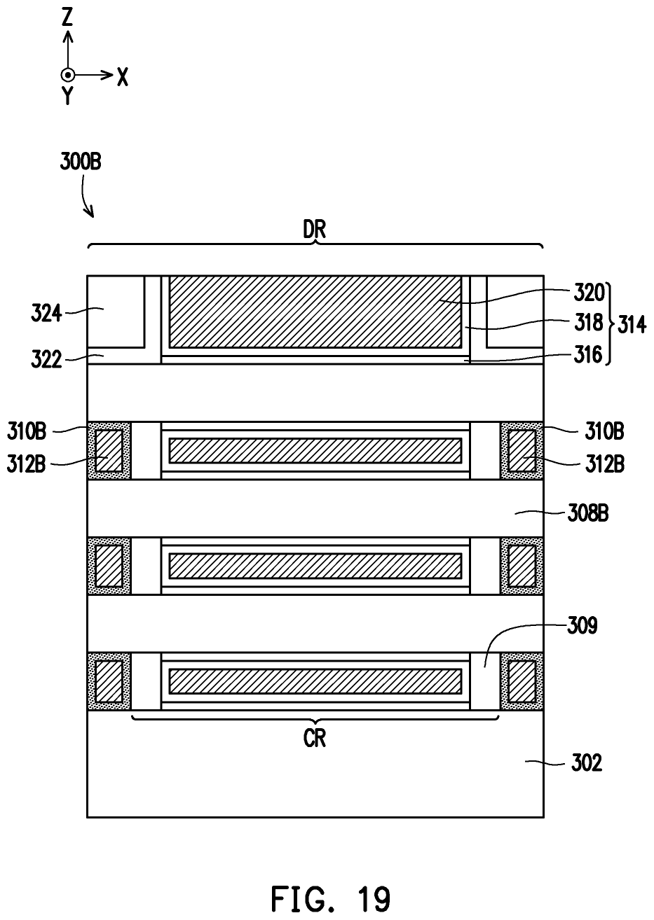

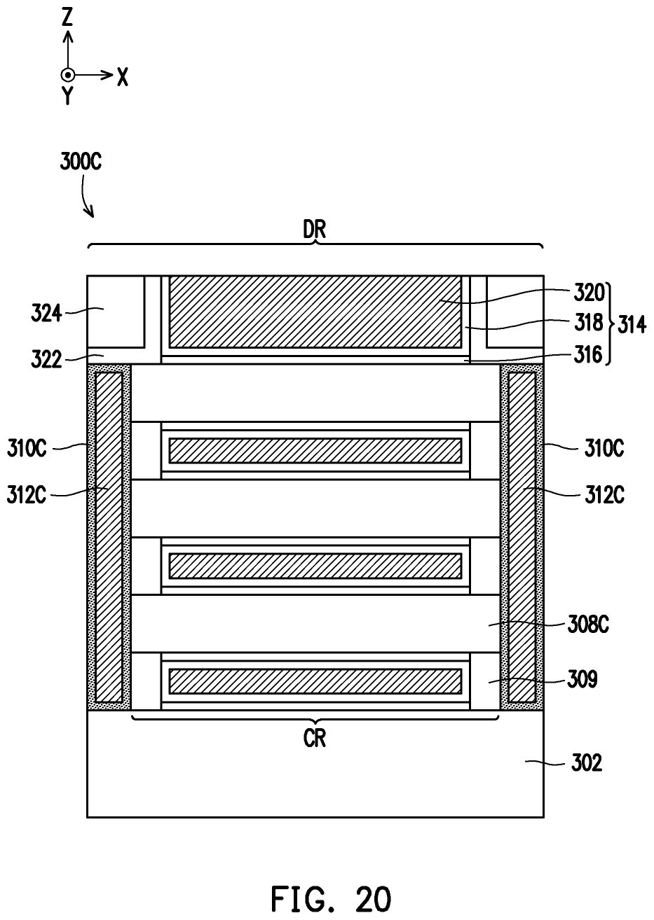

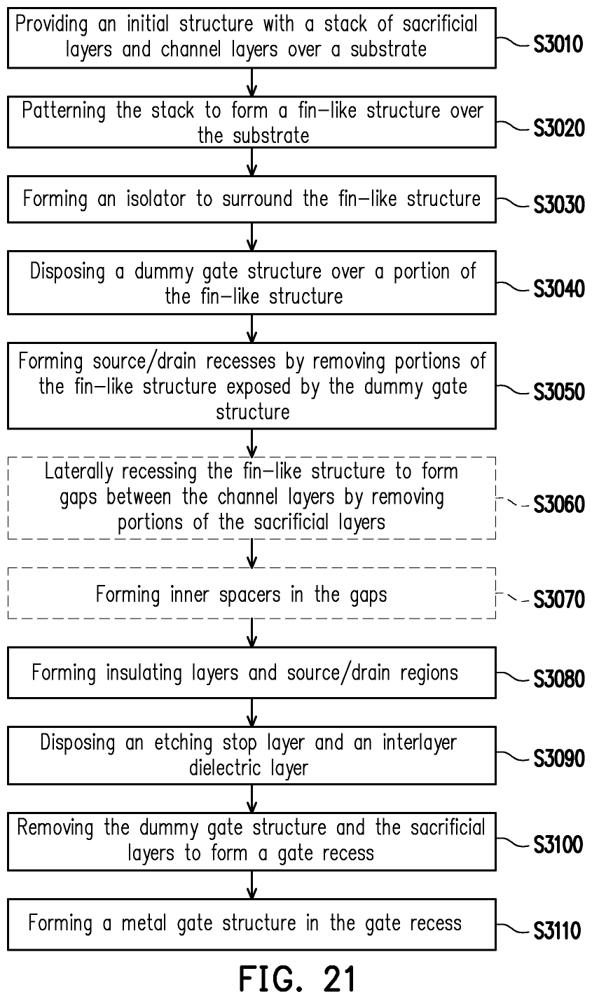

FIG. 18 is a schematic cross-sectional view showing a semiconductor device in accordance with some embodiments of the disclosure. FIG. 19 and FIG. 20 are schematic cross-sectional views showing a semiconductor device in accordance with alternative embodiments of the disclosure. The exemplary structures shown in FIG. 19 and FIG. 20 may be fabricated following the process steps as described in the embodiments as shown from FIG. 1 to FIG. 9 and/or FIG. 18, and similar materials may be used as described in the previous embodiments may be used. However, it is understood that any other compatible process steps or methods or any other suitable materials may be utilized and comprehensible modifications or adjustments may be made for forming the exemplary structure of this disclosure. FIG. 21 is a flow chart illustrating a method for manufacturing a semiconductor device in accordance with some embodiments of the disclosure.

Referring to FIG. 18, in some embodiments, a semiconductor device 300A includes a substrate 302, a plurality of channel layers 308A disposed on the substrate 302 and stacked vertically, a gate structure 314 disposed on the substrate 302 and surrounding the channel layers 308A, source/drain regions 312A disposed on the substrate 302 and each disposed between two adjacent channel layers 308A, insulating layers 310A disposed between the source/drain regions 312A and the channel layers 308A, and a plurality of inner spacers 309 disposed on the substrate 302 and each disposed between two adjacent channel layers 308A, where the inner spacers 309 are disposed between the gate structure 314 and the source/drain regions 312A. As shown in FIG. 18, the insulating layers 310A may be interposed between the source/drain regions 312A and the channel layers 308A, and may physically separate the source/drain regions 312A from the channel layers 308A. For example, sidewalls of the source/drain regions 312A are free from the insulating layers 310A. In the case, the regions of the channel layers 308A located between the source/drain regions 312A and over (e.g., overlapped with) the gate structure 314 may function as a channel region CR (or may be referred to as an active channel region) of a transistor, as shown in FIG. 18. In some embodiments, the source/drain regions 312A are electrically connected (e.g. top-contacted) with the channel region CR (channel layer) of the transistor. In some embodiments, the source/drain regions 312A are electrically connected (e.g. top-contacted) with the channel region CR (channel layer) of the transistor. On the other hand, the portions of the channel layer 308A located outside the source/drain regions 312A are electrically floated and functionally futile.

For example, the gate structure 316 surrounds (e.g., wraps around) the channel layers 308A, as shown in FIG. 18. In some embodiments, the gate structures 314 includes an interfacial (IL) layer 316, a gate dielectric layer 318, and a gate electrode 320. For example, the gate electrode 320 is separated from the source/drain regions 312A by the inner spacers 309 and the gate dielectric layer 318, and the gate electrode 320 is separated from the channel layers 308A by the gate dielectric layer 318 and the IL layer 316. The gate dielectric layer 318 may be referred to as a gate dielectric layer of the transistor, and the gate electrode 320 may be referred to as a gate of the transistor. The gate structure 314 may be referred to as a metal gate structure of the transistor. Alternatively, the gate structure 314 may further include one or more work function layer (not shown) disposed between the gate dielectric layer 318 and the gate electrode 320. In some embodiments, the semiconductor device 300A is referred to as a GAA transistor. In some embodiments, the semiconductor device 300A further includes contacts (not shown in FIG. 18) respectively in contact with the source/drain regions 312A and the gate structure 314. In some embodiments, the semiconductor device 300A further includes an ILD layer 324 to covering up the source/drain regions 312A and at least laterally covering the contacts. In some embodiments, the semiconductor device 300A further includes an etching stop layer 322 prior to the formation of the ILD layer 324 for assisting the formation of the contacts in the ILD layer 324 without damages to the source/drain regions 312A and the gate structure 314.

In some embodiments, each of the channel layers 308A has a thickness of about 0.3 nm to about 10 nm, as measured along the direction Z. In one embodiment, each of the channel layers 308A includes one or a few atomic layers of the low dimensional materials. Each atomic layer of the low dimensional materials may have a thickness of about 0.3 nm to about 1 nm. For example, each of the channel layer 308A includes one to ten atomic layers of the low dimensional materials. Each of the channel layer 308A may include 1, 2, 3, 4, 5, 6, 7, 8, 9, or 10 atomic layers of the low dimensional materials. The insulating layers 310A may have a thickness of about 0.5 nm to about 3 nm, as measured along the direction Z. The details of each of the substrate 302, the insulating layer 310A, the source/drain regions 312A, the gate dielectric layer 318, the gate electrode 320, the contacts, the etching stop layer 322, and the ILD layer 324 are respectively similar to or substantially identical to the details of each of the substrate 102, the insulating layer 110A, the source/drain regions 112, the gate dielectric layer 114, the gate electrode 116, the contacts 120, 122, the etching stop layer, and the ILD layer 118 as previously described in FIG. 1 through FIG. 9, and thus are not repeated herein.

For one non-limiting example, the formation of the semiconductor device 300A includes, but not limited to, providing an initial structure with a stack of sacrificial layers and channel layers over a substrate (step 3010 of FIG. 21), where the sacrificial layers and the channel layers are alternatively arranged on the substrate along the direction Z; patterning the stack to form a fin-like structure over the substrate (step 3020 of FIG. 21), where the fin-like structure is confined by a trench formed in the stack (e.g., by performing photolithography and etching process); forming an (dielectric) isolator to surround the fin structure (step 3030 of FIG. 21), where the isolator is formed in the trenches, and a surface of the fin-like structure protrudes from a surface of the isolator disposed inside the trench; disposing a dummy gate structure over a portion of the fin-like structure (step 3040 of FIG. 21), where portions of the fin-like structure is exposed by the dummy gate structure; forming source/drain recesses by removing portions of the fin-like structure exposed by the dummy gate structure (step 3050 of FIG. 21) through etching process, where sidewalls of the sacrificial layers and sidewalls of the channel layers of the fin-like structure are substantially aligned; laterally recessing the fin-like structure to form gaps between the channel layers by removing portions of the sacrificial layers (step 3060 of FIG. 21) through etching process, where the sacrificial layers are laterally recessed through etching process, and the sidewalls of the sacrificial layers and the sidewalls of the channel layers of the fin-like structure are not aligned; forming inner spacers in the gaps (step 3070 of FIG. 21), where the gaps are not completely filled by the inner spacers, and sidewalls of the inner spacers are not aligned with the sidewalls of the channel layers; forming insulating layers and source/drain regions (step 3080 of FIG. 21, similar to the process(es) as described in FIG. 2 through FIG. 8, FIGS. 12-13, and/or FIG. 14), where the insulating layers and source/drain regions are formed in the gaps to fill up the gaps, and sidewalls of the source/drain regions and sidewall of the insulating layer are substantially aligned with the sidewalls of the channel layers; disposing an etching stop layer and an interlayer dielectric (ILD) layer (step 3090 of FIG. 21), where the etching stop layer is formed prior to the formation of the ILD layer; removing the dummy gate structure and the sacrificial layers to form a gate recess (step 3100 of FIG. 21), where by etching process, the dummy gate is removed to form a trench opening and the sacrificial layers are removed to form a plurality of cavities, and the trench opening and the cavities are spatially communicated to each other; and forming a metal gate structure in the gate recess (step 3110 of FIG. 21), where the metal gate structure is formed in the trench opening and cavities to surround the channel layers. The removal of the sacrificial layers may be considered as a process of “channel release”, and the replacement of dummy gate structure with the metal gate structure may be considered as a process of “gate replacement”. The etching process may include a dry etch, a wet etch, or a combination thereof.

The sacrificial layers (not shown) and the channel layers (e.g., 308A) may have different materials (or compositions) that may provide for different oxidation rates and/or different etch selectivity between the layers. For example, the sacrificial layers are formed of the same material as the channel layers, while the sacrificial layers may be formed of a different material which may be selectively removed with respect to the material of the substrate and the channel layers. In some embodiments, the material of the sacrificial layers includes silicon germanium (SiGe). For example, germanium (Ge) may include about 15% to 35% of the sacrificial layers of SiGe in molar ratio. In some embodiments, the channel layers include silicon (Si), where each of the s channel layers may be undoped or substantially dopant-free. In some embodiment, the patterning the stack may be performed by an etching process. The etching process may include a dry etch, a wet etch, or a combination thereof. The stack disposed on the substrate (e.g., 302) may be patterned by etching, where the fin-like structure may be in form of a strip pattern extending along the direction X or the direction Y. The isolator (not shown, sometimes referred to as shallow trench isolation (STI) structure) may be formed via the forming process and material of the isolation structure 103 as described in FIG. 1 through FIG. 9.

In embodiments where the fin-like structure is extended along the direction X, the dummy gate structure (not shown) may be extended along the direction Y. Alternatively in embodiments where the fin-like structure is extended along the direction Y, the dummy gate structure may be extended along the direction X. The dummy gate structure may be referred to as a sacrificial gate structure, sacrificial gate, or a dummy gate. In some embodiments, the dummy gate structure includes a dummy gate dielectric layer (not shown) and a dummy gate electrode (not shown). A material of the dummy gate dielectric layer may include silicon oxide, silicon nitride, silicon oxynitride, the like or combinations thereof, whereas a material of the dummy gate electrode may include polysilicon. In addition, methods for forming the dummy gate dielectric layer and the dummy gate electrode may respectively include a deposition process, (such as a CVD process or an ALD process) and an etching process.

Gate spacers (not shown) may be formed at two opposite sides of the dummy gate structure. A material of the gate spacers may include silicon oxide, silicon nitride, silicon carbide, silicon oxynitride (SiON), silicon carbide nitride (SiCN), silicon oxycarbide (SiOC), silicon carbide oxynitride (SiOCN), the like or combinations thereof, and a method for forming the gate spacers may include a deposition process, such as a CVD process or an ALD process. The material of the gate spacers is different from the materials of the insulator, the sacrificial layers, the channel layers, and the substrate, in one embodiment. However, the disclosure is not limited thereto; alternatively, the material of the gate spacers may be the same as the material of one or more than one of the insulator, the sacrificial layers, the channel layers, and the substrate.

In some embodiments, the inner spacers (e.g., 309) are formed in the gaps by partially filling an insulating material in the gaps, where outer sidewalls of the inner spacers are not aligned with the sidewalls of the channel layers. A material of the insulating material for forming the inner spacers may include silicon oxide, silicon nitride, silicon carbide, silicon carbide nitride, silicon oxide carbide, silicon carbide oxynitride, or other suitable dielectric materials or combinations thereof. In some embodiments, the insulating material is formed by using a deposition process (e.g., a CVD process or an ALD process), and the portions of the insulating material are removed by using an etching process.

In some embodiments, the insulating layers (e.g., 310A) may be formed by oxidation process as described in FIG. 2 through FIG. 8, where a two-dimensional material layer (not shown) is conformally formed on the sidewall of the fin-like structure and further extends into the gaps as liners, the oxidation process is performed to convert horizontal portions of the two-dimensional material layer into the insulating layers, and the unconverted portion of the two-dimensional material layer are removed so to expose sacrificial layers and the channel layers. For example, after the formation of the insulating layers, the source/drain regions (e.g., 312A) is formed in the gaps by deposition and etching process.

In some embodiments, the etching stop layer (e.g., 322) is disposed on and completely covers the fin-like structure, the isolator, the source/drain regions, the dummy gate structure, and the gate spacers. The etching stop layer includes, for example, a suitable material such as silicon nitride, silicon oxynitride, silicon nitride with oxygen or carbon elements, the like or combinations thereof. In some embodiments, the etching stop layer is deposited by using processes such as CVD (e.g., high density plasma (HDP) CVD or sub-atmospheric CVD (SACVD)), ALD, molecular layer deposition (MLD), or other suitable methods. The etching stop layer functions as a protection layer that effectively blocks water or moisture from penetrating into the elements underlying thereto or damages from the subsequent process(es) such as an etching process. The etching stop layer may be referred to as a protection layer or a contact etch stop (CES) layer. A thickness of the etching stop layer may be in a range of about 1 nm to about 5 nm. Although other value of the thickness of the etching stop layer is possible depending on product and process requirements.

In some embodiments, the ILD layer (e.g., 324) is formed on the etching stop layer to embed the fin-like structure, the isolator, the source/drain regions, the dummy gate structure, and the gate spacers in the ILD layer. Prior to the removal of the dummy gate structure and the sacrificial layer, a planarization process may be performed onto the ILD layer to expose the dummy gate structure from the ILD layer. The planarization process, for example, includes a grinding process, a CMP process, an etching process, or combinations thereof. The etching process may include a dry etch, a wet etch, or a combination thereof.

After removing the dummy gate structure and the sacrificial layers, the IL layer (e.g., 316), the gate dielectric layer (e.g., 318), and the gate electrode (e.g., 320) is sequentially formed in the space (constituted by trench opening/cavities) to form the metal gate structure (e.g., 314), in some embodiments. The interfacial layer may include a dielectric material such as silicon oxide layer or silicon oxynitride, and may be formed by a deposition process such as ALD, CVD, and/or other suitable deposition methods. The interfacial layer may be adapted to provide a good interface between the semiconductor surface (i.e., the channel layer) and a gate insulator (i.e., the gate dielectric layer) and to suppress the mobility degradation of the channel carrier of the transistors. A material of the gate dielectric layer may include a high-k dielectric material. In some embodiments, the low-k dielectric material is generally dielectric materials having a dielectric constant greater than about 4, greater than about 12, greater than about 16, or even greater than about 20. Examples of the high-k dielectric material may include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer may be one-layer structure or a multi-layer structure of different sublayers. The gate dielectric layer may be referred to as a high-k dielectric layer. A method for forming the gate dielectric layers may include a deposition process, such as a CVD process or an ALD process. A material of the gate electrode may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. A method for forming the gate electrode may include a deposition process (e.g., a CVD process or an ALD process), a plating process (e.g., an electrical plating process or an electroless plating process) or a combination thereof.

In some embodiments, one or more work function layer (not shown) is formed between each gate dielectric layer and the overlying gate electrode. A material of the work function layer may include p-type work function metals or n-type work function metals. For example, the p-type work function metals include TiN, TaN, Ru, Mo, Al, WN, ZrSi₂, MoSi₂, TaSi₂, NiSi₂, WN, other suitable p-type work function materials, or combinations thereof. For example, the n-type work function metals include Ti, Ag, TaAl, TaAlC, TiAlN, TaC, TaCN, TaSiN, Mn, Zr, other suitable n-type work function materials, or combinations thereof. In some embodiments, the method of forming the work function layer includes performing at least one suitable deposition technique, such as CVD (e.g., PECVD), ALD (e.g., remote plasma atomic layer deposition (RPALD), plasma enhanced atomic layer deposition (PEALD), molecular beam deposition (MBD), or the like. The work function layer may serve the purpose of adjusting threshold voltage (Vt) of the transistors.

As described above, owing to the position of the insulating layer 310A, the source/drain regions 312A and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 300A. That is, the Schottky barrier height can be greatly and effectively reduced, and the reliability of the semiconductor device 300A is ensured. In addition, by controlling a layer-number of the atomic layers constituting the channel layer 308A serving as the channel region CR, an effective channel width can be greatly improved while no change in the size of the footprint of the channel region CR in the semiconductor device 300A. For example, by increasing the layer-number of the atomic layers constituting the channel layer 308A serving as the channel region CR, the effective channel width of the semiconductor device 300A can be increased.

However, the disclosure is not limited thereto; in alternative embodiments, the inner spacers 309 may be omitted. In such alternative embodiments, the gate electrode 320 is separated from the source/drain regions 312A by the gate dielectric layer 318, and the gate electrode 320 is separated from the channel layers 308A by the gate dielectric layer 318 and the IL layer 316.

Referring to FIG. 19, in some embodiments, a semiconductor device 300B includes a substrate 302, a plurality of channel layers 308B disposed on the substrate 302 and stacked vertically, a gate structure 314 disposed on the substrate 302 and surrounding the channel layers 308B, source/drain regions 312B disposed on the substrate 302 and each disposed between two adjacent channel layers 308B, insulating layers 310B disposed between the source/drain regions 312B and the channel layers 308B, and a plurality of inner spacers 309 disposed on the substrate 302 and each disposed between two adjacent channel layers 308B, where the inner spacers 309 are disposed between the gate structure 314 and the source/drain regions 312B. As shown in FIG. 19, the insulating layers 310B may be interposed between the source/drain regions 312B and the channel layers 308B and between the inner spacers 309 and the source/drain regions 312B, and may physically separate the source/drain regions 312B from the channel layers 308B and the inner spacers 309. For example, a top surface, a bottom surface and sidewalls conning the top surface and the bottom surface of the source/drain regions 312B are completely covered by the insulating layers 310B. That is, an outer surface of each of the source/drain regions 312B is completely wrapped by the insulating layer 310B. In the case, the regions of the channel layers 308B located between the source/drain regions 312B and over (e.g., overlapped with) the gate structure 314 may function as a channel region CR (or may be referred to as an active channel region) of a transistor, as shown in FIG. 19. In some embodiments, the source/drain regions 312B are electrically connected (e.g. top-contacted) with the channel region CR (channel layer) of the transistor. In some embodiments, the source/drain regions 312B are electrically connected (e.g. top-contacted) with the channel region CR (channel layer) of the transistor. On the other hand, the portions of the channel layer 308B located outside the source/drain regions 312B are electrically floated and functionally futile.

For example, the gate structure 316 surrounds (e.g., wraps around) the channel layers 308B, as shown in FIG. 19. In some embodiments, the gate structures 314 includes an IL layer 316, a gate dielectric layer 318, and a gate electrode 320. For example, the gate electrode 320 is separated from the source/drain regions 312B by the insulating layer 310B, the inner spacers 309 and the gate dielectric layer 318, and the gate electrode 320 is separated from the channel layers 308B by the gate dielectric layer 318 and the IL layer 316. The gate dielectric layer 318 may be referred to as a gate dielectric layer of the transistor, and the gate electrode 320 may be referred to as a gate of the transistor. The gate structure 314 may be referred to as a metal gate structure of the transistor. Alternatively, the gate structure 314 may further include one or more work function layer (not shown) disposed between the gate dielectric layer 318 and the gate electrode 320. In some embodiments, the semiconductor device 300B is referred to as a GAA transistor. In some embodiments, the semiconductor device 300B further includes contacts (not shown in FIG. 19) respectively in contact with the source/drain regions 312B and the gate structure 314. In some embodiments, the semiconductor device 300B further includes an ILD layer 324 to covering up the source/drain regions 312B and at least laterally covering the contacts. In some embodiments, the semiconductor device 300B further includes an etching stop layer 322 prior to the formation of the ILD layer 324 for assisting the formation of the contacts in the ILD layer 324 without damages to the source/drain regions 312B and the gate structure 314.

In some embodiments, each of the channel layers 308B has a thickness of about 0.3 nm to about 10 nm, as measured along the direction Z. In one embodiment, each of the channel layers 308B includes one or a few atomic layers of the low dimensional materials. Each atomic layer of the low dimensional materials may have a thickness of about 0.3 nm to about 1 nm. For example, each of the channel layer 308B includes one to ten atomic layers of the low dimensional materials. Each of the channel layer 308B may include 1, 2, 3, 4, 5, 6, 7, 8, 9, or 10 atomic layers of the low dimensional materials. The insulating layers 310B may have a thickness of about 0.5 nm to about 3 nm, as measured along the direction Z. The details of each of the substrate 302, the channel layer 308B, the inner spacers 309, the insulating layer 310B, the source/drain regions 312B, the gate structure 314 (including the IL layer 316, the gate dielectric layer 318, and the gate electrode 320), the etching stop layer 322, the ILD layer 324, and the contacts are respectively similar to or substantially identical to the details of each of the substrate 302, the channel layer 308A, the inner spacers 309, the insulating layer 310A, the source/drain regions 312A, the gate structure 314 (including the IL layer 316, the gate dielectric layer 318, and the gate electrode 320), the etching stop layer 322, the ILD layer 324, and the contacts as previously described in FIG. 18, and thus are not repeated herein.

For one non-limiting example, the formation of the semiconductor device 300B includes, but not limited to, providing an initial structure with a stack of sacrificial layers and channel layers over a substrate (step 3010 of FIG. 21), where the sacrificial layers and the channel layers are alternatively arranged on the substrate along the direction Z; patterning the stack to form a fin-like structure over the substrate (step 3020 of FIG. 21), where the fin-like structure is confined by a trench formed in the stack (e.g., by performing photolithography and etching process); forming an (dielectric) isolator to surround the fin structure (step 3030 of FIG. 21), where the isolator is formed in the trenches, and a surface of the fin-like structure protrudes from a surface of the isolator disposed inside the trench; disposing a dummy gate structure over a portion of the fin-like structure (step 3040 of FIG. 21), where portions of the fin-like structure is exposed by the dummy gate structure; forming source/drain recesses by removing portions of the fin-like structure exposed by the dummy gate structure (step 3050 of FIG. 21) through etching process, where sidewalls of the sacrificial layers and sidewalls of the channel layers of the fin-like structure are substantially aligned; laterally recessing the fin-like structure to form gaps between the channel layers by removing portions of the sacrificial layers (step 3060 of FIG. 21) through etching process, where the sacrificial layers are laterally recessed through etching process, and the sidewalls of the sacrificial layers and the sidewalls of the channel layers of the fin-like structure are not aligned; forming inner spacers in the gaps (step 3070 of FIG. 21), where the gaps are not completely filled by the inner spacers, and sidewalls of the inner spacers are not aligned with the sidewalls of the channel layers; forming insulating layers and source/drain regions (step 3080 of FIG. 21, similar to the process(es) of FIGS. 10-11, FIG. 15, and/or FIG. 16), where the insulating layers and source/drain regions are formed in the gaps to fill up the gaps, the outer surfaces of the source/drain regions are completely covered by the insulting layer, and sidewalls of the insulating layer are substantially aligned with the sidewalls of the channel layers; disposing an etching stop layer and an interlayer dielectric (ILD) layer (step 3090 of FIG. 21), where the etching stop layer is formed prior to the formation of the ILD layer; removing the dummy gate structure and the sacrificial layers to form a gate recess (step 3100 of FIG. 21), where by etching process, the dummy gate is removed to form a trench opening and the sacrificial layers are removed to form a plurality of cavities, and the trench opening and the cavities are spatially communicated to each other and thus form the gate recess; and forming a metal gate structure in the gate recess (step 3110 of FIG. 21), where the metal gate structure is formed in the trench opening and cavities to surround the channel layers. In some embodiments, the insulating layers (e.g., 310B) may be formed by forming the source/drain regions (e.g., 312B) inside the gaps; and performing self-limiting oxidation process onto the source/drain regions, so to form the insulating layers. The removal of the sacrificial layers may be considered as a process of “channel release”, and the replacement of dummy gate structure with the metal gate structure may be considered as a process of “gate replacement”. The etching process may include a dry etch, a wet etch, or a combination thereof. In some embodiment, gate spacers (not shown) are formed at two opposite sides of the dummy gate structure.

As described above, owing to the position of the insulating layer 310B, the source/drain regions 312B and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 300B. That is, the Schottky barrier height can be greatly and effectively reduced, and the reliability of the semiconductor device 300B is ensured. In addition, by controlling a layer-number of the atomic layers constituting the channel layer 308B serving as the channel region CR, an effective channel width can be greatly improved while no change in the size of the footprint of the channel region CR in the semiconductor device 300B. For example, by increasing the layer-number of the atomic layers constituting the channel layer 308B serving as the channel region CR, the effective channel width of the semiconductor device 300B can be increased.

However, the disclosure is not limited thereto; in alternative embodiments, the inner spacers 309 may be omitted. In such alternative embodiments, the gate electrode 320 is separated from the source/drain regions 312B by the insulating layer 310B and the gate dielectric layer 318, and the gate electrode 320 is separated from the channel layers 308B by the gate dielectric layer 318 and the IL layer 316.

Referring to FIG. 20, in some embodiments, a semiconductor device 300C includes a substrate 302, a plurality of channel layers 308C disposed on the substrate 302 and stacked vertically, a gate structure 314 disposed on the substrate 302 and surrounding the channel layers 308C, source/drain regions 312C disposed on the substrate 302 and sandwiching the channel layers 308C therebetween, insulating layers 310C surrounding the source/drain regions 312C and disposed between the source/drain regions 312C and the channel layers 308C, and a plurality of inner spacers 309 disposed on the substrate 302 and each disposed between two adjacent channel layers 308C, where the inner spacers 309 are disposed between the gate structure 314 and the source/drain regions 312C and between the gate structure 314 and the insulating layer 310C. As shown in FIG. 20, the insulating layers 310C may be interposed between the source/drain regions 312C and the channel layers 308C and between the inner spacers 309 and the source/drain regions 312C, and may physically separate the source/drain regions 312C from the channel layers 308C and the inner spacers 309. For example, a top surface, a bottom surface and sidewalls conning the top surface and the bottom surface of the source/drain regions 312C are completely covered by the insulating layers 310C. That is, an outer surface of each of the source/drain regions 312C is completely wrapped by the insulating layer 310C. In the case, the regions of the channel layers 308C located between the source/drain regions 312C and over (e.g., overlapped with) the gate structure 314 may function as a channel region CR (or may be referred to as an active channel region) of a transistor, as shown in FIG. 20. In some embodiments, the source/drain regions 312C are electrically connected (e.g. edge-contacted) with the channel region CR (channel layer) of the transistor. In some embodiments, the source/drain regions 312C are electrically connected (e.g. edge-contacted) with the channel region CR (channel layer) of the transistor. On the other hand, the portions of the channel layer 308C located outside the source/drain regions 312C are electrically floated and functionally futile.

For example, the gate structure 316 surrounds (e.g., wraps around) the channel layers 308C, as shown in FIG. 20. In some embodiments, the gate structures 314 includes an IL layer 316, a gate dielectric layer 318, and a gate electrode 320. For example, the gate electrode 320 is separated from the source/drain regions 312C by the insulating layer 310C, the inner spacers 309 and the gate dielectric layer 318, and the gate electrode 320 is separated from the channel layers 308B by the gate dielectric layer 318 and the IL layer 316. The gate dielectric layer 318 may be referred to as a gate dielectric layer of the transistor, and the gate electrode 320 may be referred to as a gate of the transistor. The gate structure 314 may be referred to as a metal gate structure of the transistor. Alternatively, the gate structure 314 may further include one or more work function layer (not shown) disposed between the gate dielectric layer 318 and the gate electrode 320. In some embodiments, the semiconductor device 300C is referred to as a GAA transistor. In some embodiments, the semiconductor device 300C further includes contacts (not shown in FIG. 20) respectively in contact with the source/drain regions 312C and the gate structure 314. In some embodiments, the semiconductor device 300C further includes an ILD layer 324 to covering up the source/drain regions 312C and at least laterally covering the contacts. In some embodiments, the semiconductor device 300C further includes an etching stop layer 322 prior to the formation of the ILD layer 324 for assisting the formation of the contacts in the ILD layer 324 without damages to the source/drain regions 312C and the gate structure 314.

In some embodiments, each of the channel layers 308C has a thickness of about 0.3 nm to about 10 nm, as measured along the direction Z. In one embodiment, each of the channel layers 308C includes one or a few atomic layers of the low dimensional materials. Each atomic layer of the low dimensional materials may have a thickness of about 0.3 nm to about 1 nm. For example, each of the channel layer 308C includes one to ten atomic layers of the low dimensional materials. Each of the channel layer 308C may include 1, 2, 3, 4, 5, 6, 7, 8, 9, or 10 atomic layers of the low dimensional materials. The insulating layers 310C may have a thickness of about 0.5 nm to about 3 nm, as measured along the direction Z. The details of each of the substrate 302, the channel layer 308C, the inner spacers 309, the insulating layer 310C, the source/drain regions 312C, the gate structure 314 (including the IL layer 316, the gate dielectric layer 318, and the gate electrode 320), the etching stop layer 322, the ILD layer 324, and the contacts are respectively similar to or substantially identical to the details of each of the substrate 302, the channel layer 308B, the inner spacers 309, the insulating layer 310B, the source/drain regions 312B, the gate structure 314 (including the IL layer 316, the gate dielectric layer 318, and the gate electrode 320), the etching stop layer 322, the ILD layer 324, and the contacts as previously described in FIG. 19, and thus are not repeated herein.

For one non-limiting example, the formation of the semiconductor device 300C includes, but not limited to, providing an initial structure with a stack of sacrificial layers and channel layers over a substrate (step 3010 of FIG. 21), where the sacrificial layers and the channel layers are alternatively arranged on the substrate along the direction Z; patterning the stack to form a fin-like structure over the substrate (step 3020 of FIG. 21), where the fin-like structure is confined by a trench formed in the stack (e.g., by performing photolithography and etching process); forming an (dielectric) isolator to surround the fin structure (step 3030 of FIG. 21), where the isolator is formed in the trenches, and a surface of the fin-like structure protrudes from a surface of the isolator disposed inside the trench; disposing a dummy gate structure over a portion of the fin-like structure (step 3040 of FIG. 21), where portions of the fin-like structure is exposed by the dummy gate structure; forming source/drain recesses by removing portions of the fin-like structure exposed by the dummy gate structure (step 3050 of FIG. 21) through etching process, where sidewalls of the sacrificial layers and sidewalls of the channel layers of the fin-like structure are substantially aligned; laterally recessing the fin-like structure to form gaps between the channel layers by removing portions of the sacrificial layers (step 3060 of FIG. 21) through etching process, where the sacrificial layers are laterally recessed through etching process, and the sidewalls of the sacrificial layers and the sidewalls of the channel layers of the fin-like structure are not aligned; forming inner spacers in the gaps (step 3070 of FIG. 21), where the gaps are filled by the inner spacers, and sidewalls of the inner spacers are substantially aligned with the sidewalls of the channel layers; forming insulating layers and source/drain regions (step 3080 of FIG. 21, similar to the process(es) of FIGS. 10-11, FIG. 15, and/or FIG. 16), where the source/drain regions are formed at two opposite sides of the channel layers 308C, the insulating layers 310C respectively cover the outer surfaces of the source/drain regions 312C, and the insulating layers 310C extends over the sidewalls of the channel layers 308C and the inner spacers being substantially aligned; disposing an etching stop layer and an interlayer dielectric (ILD) layer (step 3090 of FIG. 21), where the etching stop layer is formed prior to the formation of the ILD layer; removing the dummy gate structure and the sacrificial layers to form a gate recess (step 3100 of FIG. 21), where by etching process, the dummy gate is removed to form a trench opening and the sacrificial layers are removed to form a plurality of cavities, and the trench opening and the cavities are spatially communicated to each other and thus form the gate recess; and forming a metal gate structure in the gate recess (step 3110 of FIG. 21), where the metal gate structure is formed in the trench opening and cavities to surround the channel layers. In some embodiments, the insulating layers (e.g., 310C) may be formed by forming the source/drain regions (e.g., 312C) at two opposite sides of the channel layers 308C; and performing self-limiting oxidation process onto the source/drain regions, so to form the insulating layers. The removal of the sacrificial layers may be considered as a process of “channel release”, and the replacement of dummy gate structure with the metal gate structure may be considered as a process of “gate replacement”. The etching process may include a dry etch, a wet etch, or a combination thereof. In some embodiment, gate spacers (not shown) are formed at two opposite sides of the dummy gate structure.

As described above, owing to the position of the insulating layer 310C, the source/drain regions 312C and the channel region CR are not directly contacted with one another, a phenomena of fermi-level pinning is greatly suppressed, and an excellent electrostatic control, a reduction in contact resistance, and high intrinsic mobility are achieved, thereby enhancing the performance of the semiconductor device 300C. That is, the Schottky barrier height can be greatly and effectively reduced, and the reliability of the semiconductor device 300C is ensured. In addition, by controlling a layer-number of the atomic layers constituting the channel layer 308C serving as the channel region CR, an effective channel width can be greatly improved while no change in the size of the footprint of the channel region CR in the semiconductor device 300C. For example, by increasing the layer-number of the atomic layers constituting the channel layer 308C serving as the channel region CR, the effective channel width of the semiconductor device 300C can be increased. Also, since the source/drain regions 312C are edge-contacted with the channel layer 308C, clear Fermi level de-pinning effect is achieved and the current injection efficiency of the semiconductor device 300C is improved.

However, the disclosure is not limited thereto; in alternative embodiments, the inner spacers 309 may be omitted. In such alternative embodiments, the gate electrode 320 is separated from the source/drain regions 312C by the insulating layer 310C and the gate dielectric layer 318, and the gate electrode 320 is separated from the channel layers 308C by the gate dielectric layer 318 and the IL layer 316.

It is understood that a plurality of isolation structures (not shown) may be included in the substrate 302 so to define one or multiple device region DR through the arrangement of the isolation structures, in the above embodiments of FIG. 18 through FIG. 20. The details of the isolation structures may be similar to or substantially identical to the details of the isolation structures 103 as previously described in FIG. 1 through FIG. 9, and thus are not repeated herein for simplicity.

In the disclosure, the formation of an insulating layer (e.g., 108A, 108B, 108C, 208A, 208B, 208C, 308A, 308B, and/or 308C) may be done by performing an oxidation process onto a channel (material) layer to convert a portion of two-dimensional material included in the channel (material) into the insulating layer or performing an self-limiting oxidation process onto a source/drain regions to convert a portion of conductive material included in the source/drain regions into the insulating layer. In such case, the process used for the formation of the insulating layer (e.g., 108A, 108B, 108C, 208A, 208B, 208C, 308A, 308B, and/or 308C) may be considered as a conversion process or a converting process. The etching process may be further involved to obtain an suitable pattern of the insulating layer (e.g., 108A, 108B, 108C, 208A, 208B, 208C, 308A, 308B, and/or 308C) by either patterning the insulating layer (e.g., 108A, 108B, 108C, 208A, 208B, 208C, 308A, 308B, and/or 308C) or the channel (material) layer.

In accordance with some embodiments, a semiconductor device includes a substrate, a channel layer, a gate structure, source/drain regions, and an insulating layer. The channel layer is disposed over the substrate. The gate structure is disposed over the channel layer. The source/drain regions are disposed over the substrate and disposed at two opposite sides of the channel layer. The insulating layer is disposed between the channel layer and the source/drain regions.

In accordance with some embodiments, a semiconductor device includes a substrate, a plurality of channels, a plurality of source/drain regions, a plurality of insulating layers, and a gate structure. The plurality of channels are vertically stacked over the substrate and separated from each other. The plurality of source/drain regions are disposed over the substrate and at two opposite sides of each of the plurality of channels. The plurality of insulating layers are respectively interposed between the plurality of source/drain regions and the plurality of channels. The gate structure engages the plurality of channels and interposes the plurality of source/drain regions.

In accordance with some embodiments, a method of manufacturing a semiconductor device includes the following steps: providing a substrate; disposing a channel layer over the substrate; forming an insulating layer over the channel layer; disposing source/drain regions over the substrate, the source/drain regions being disposed at two opposite sides of the channel layer, and the insulating layer be disposed between the channel layer and the source/drain regions; and forming a gate structure over the substrate, the gate structure being disposed over the channel layer.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a substrate;
a channel layer, disposed over the substrate;
a gate structure, disposed over the channel layer;
source/drain regions, disposed over the substrate and disposed at two opposite sides of the channel layer; and
an insulating layer, disposed between the channel layer and the source/drain regions.

2. The semiconductor device of claim 1, wherein the channel layer is disposed between the substrate and the gate structure, and the gate structure is disposed between the source/drain regions.

3. The semiconductor device of claim 2, wherein the insulating layer and the source/drain regions penetrate through the channel layer, and a bottom surface and a sidewall connecting to the bottom surface of the source/drain regions are in contact with the insulating layer.

4. The semiconductor device of claim 3, wherein the source/drain regions are protruded out of the channel layer.

5. The semiconductor device of claim 1, wherein the gate structure is disposed between the substrate and the channel layer, and the channel layer is disposed between the gate structure and the source/drain regions.

6. The semiconductor device of claim 5, wherein outer surfaces of the source/drain regions are in contact with the insulating layer.

7. The semiconductor device of claim 6, wherein the insulating layer and the source/drain regions penetrate through the channel layer.

8. The semiconductor device of claim 1, wherein a material of the channel layer includes a low-dimensional material, and a material of the insulating layer includes an oxide material.

9. The semiconductor device of claim 1, further comprising a gate dielectric layer located between the gate structure and the channel layer.

10. A semiconductor device, comprising:
a substrate;
a plurality of channels, vertically stacked over the substrate and separated from each other;
a plurality of source/drain regions, disposed over the substrate and at two opposite sides of each of the plurality of channels;
a plurality of insulating layers, respectively interposed between the plurality of source/drain regions and the plurality of channels; and
a gate structure, engaging the plurality of channels and interposing the plurality of source/drain regions.

11. The semiconductor device of claim 10, wherein in a cross-section of the semiconductor device, each of the plurality of source/drain regions is disposed between two adjacent channels of the plurality of channels along a vertical direction.

12. The semiconductor device of claim 11, wherein the plurality of insulating layers are disposed between the plurality of source/drain regions and the plurality of channels along the vertical direction,
wherein sidewalls of the plurality of channels are substantially aligned with sidewalls of the plurality of source/drain regions and sidewalls of the plurality of insulating layers.

13. The semiconductor device of claim 11, wherein the plurality of insulating layers are disposed between the plurality of source/drain regions and the plurality of channels along the vertical direction and are disposed between the plurality of source/drain regions and the gate structure along a horizontal direction,
wherein sidewalls of the plurality of channels are substantially aligned with sidewalls of the plurality of insulating layers.

14. The semiconductor device of claim 10, wherein in a cross-section of the semiconductor device, the plurality of channels are interposed between the plurality of source/drain regions along a horizontal direction.

15. The semiconductor device of claim 14, wherein the plurality of insulating layers are disposed between the plurality of source/drain regions and the plurality of channels along the horizontal direction and are disposed between the plurality of source/drain regions and the gate structure along the horizontal direction,
wherein outer surfaces of the plurality of source/drain regions are in contact with the plurality of insulating layers, respectively.

16. The semiconductor device of claim 10, wherein a material of the plurality of channels includes a transition metal dichalcogenide (TMD) denoted as MX₂, where M is a molybdenum (Mo) or tungsten (W) and X is sulfur (S), selenium (Se) or tellurium (Te), and a material of the plurality of insulating layers includes an oxide of Mo or W.

17. A method of manufacturing a semiconductor device, comprising:
providing a substrate;
disposing a channel layer over the substrate;
forming an insulating layer over the channel layer;
disposing source/drain regions over the substrate, the source/drain regions being disposed at two opposite sides of the channel layer, and the insulating layer be disposed between the channel layer and the source/drain regions; and
forming a gate structure over the substrate, the gate structure being disposed over the channel layer.

18. The method of claim 17, wherein disposing the channel layer over the substrate, forming the insulating layer over the channel layer, and disposing the source/drain regions are prior to forming the gate structure over the substrate, and disposing the channel layer over the substrate is prior to forming the insulating layer over the channel layer and disposing the source/drain regions, wherein:
forming the insulating layer over the channel layer is prior to disposing the source/drain regions, which is done by performing an oxidation process to the channel layer to convert a portion of the channel layer into the insulating layer, and disposing the source/drain regions on the insulating layer and over the substrate; or
disposing the source/drain regions is prior to forming the insulating layer over the channel layer, which is done by disposing the source/drain regions on the channel layer and over the substrate, and performing a self-limiting oxidation process to the source/drain regions to convert a outermost portion of each of the source/drain regions into the insulating layer.

19. The method of claim 17, wherein forming the gate structure over the substrate is prior to disposing the channel layer over the substrate, forming the insulating layer over the channel layer, and disposing the source/drain regions, and disposing the channel layer over the substrate is prior to forming the insulating layer over the channel layer and disposing the source/drain regions, wherein:
forming the insulating layer over the channel layer is prior to disposing the source/drain regions, which is done by performing an oxidation process to the channel layer to convert a portion of the channel layer into the insulating layer, and disposing the source/drain regions on the insulating layer and over the substrate; or
disposing the source/drain regions is prior to forming the insulating layer over the channel layer, which is done by disposing the source/drain regions on the channel layer and over the substrate, and performing a self-limiting oxidation process to the source/drain regions to convert a outermost portion of each of the source/drain regions into the insulating layer.

20. The method of claim 17, further comprising:
patterning the channel layer to form a plurality of openings penetrating through the channel layer, wherein the insulating layer and the source/drain regions are further disposed in the plurality of openings formed in the channel layer.
